(19) United States
(12) Patent Application Publication
(10) Pub. No.: US 2024/0191096 A1
(43) Pub. Date: Jun. 13, 2024

(54) UNDERCOAT AGENT, AND METHOD FOR PRODUCING STRUCTURE INCLUDING PHASE-SEPARATED STRUCTURE

(71) Applicant: TOKYO OHKA KOGYO CO., LTD., Kawasaki-shi (JP)

(72) Inventors: Junichi Tsuchiya, Kawasaki-shi (JP); Shota Iino, Kawasaki-shi (JP)

(21) Appl. No.: 18/491,270

(22) Filed: Oct. 20, 2023

(30) Foreign Application Priority Data
Oct. 25, 2022 (JP) 2022-170478
Apr. 7, 2023 (JP) 2023-062735

(51) Int. Cl. C09D 153/00; C09D 5/00; G03F 7/11; G03F 7/26

(52) U.S. Cl. CPC C09D 153/00; C09D 5/002; G03F 7/11; G03F 7/26

(57) ABSTRACT

An undercoat agent that is used for subjecting a layer including a block copolymer to phase separation on a substrate, the undercoat agent containing a resin component (A1) having a constitutional unit (u1) represented by General Formula (u1) and a constitutional unit (u2) represented by General Formula (u2). In General Formula (u1), R¹¹ represents a hydrogen atom, an alkyl group having 1 to 5 carbon atoms, or a halogenated alkyl group having 1 to 5 carbon atoms, R¹² represents a substituent, and n represents an integer of 0 to 5. In General Formula (u2), R² represents a hydrogen atom, an alkyl group having 1 to 5 carbon atoms, or a halogenated alkyl group having 1 to 5 carbon atoms, L² represents a single bond or a divalent linking group, and Y² represents a divalent linking group having 5 to 15 carbon atoms

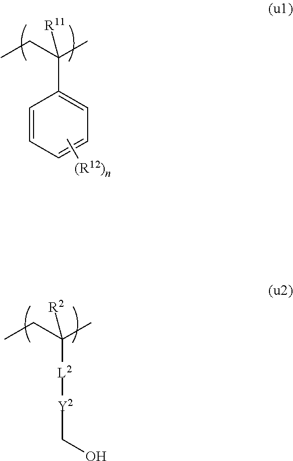

### BACKGROUND OF THE INVENTION

### Field of the Invention

The present invention relates to an undercoat agent and a method for producing a structure including a phase-separated structure.

Priority is claimed on Japanese Patent Application No. 2022-170478, filed on Oct. 25, 2022, and Japanese Patent Application No. 2023-062735, filed on Apr. 7, 2023, the contents of which are incorporated herein by reference.

### Description of Related Art

In recent years, along with further miniaturization of large-scale integrated circuits (LSI), a technology for processing finer structures has been demanded. In response to such a demand, there has been developed a technology for forming a finer structure by utilizing a phase-separated structure formed by self-organization of a block copolymer in which blocks incompatible to each other are bonded together.

In order to utilize the phase-separated structure of the block copolymer, it is considered essential to form self-organized nanostructures, which are formed by micro-phase separation, only in a specific region and arrange the nanostructures in a desired direction. In order to realize the position control and orientation control of these nanostructures, processes such as graphoepitaxy for controlling the phase separation pattern by a guide pattern, and chemical epitaxy for controlling the phase separation pattern by the difference in the chemical state of the substrate, have been proposed (see, for example, Proceedings of SPIE, Vol. 7637, No. 76370G-1, 2010).

As a method for forming a fine pattern by subjecting a block copolymer to phase separation, for example, a method for forming an undercoat agent layer on a substrate has been disclosed. For example, Japanese Patent No. 6475963 discloses an undercoat agent including a constitutional unit derived from styrene and a constitutional unit derived from hydroxyethyl acrylate.

### SUMMARY OF THE INVENTION

In order to obtain an ideal phase-separated structure by subjecting a block copolymer to phase separation, it is necessary to control the surface free energy of an undercoat agent layer. However, the undercoat agent of the related art as disclosed in Japanese Patent No. 6475963 is such that the margin of the baking temperature at the time of forming an undercoat agent layer is small, and it is difficult to sufficiently control the surface state of the undercoat agent layer.

Therefore, the surface of the undercoat agent layer cannot be sufficiently controlled to be hydrophobic, and defective phase separation is likely to occur. In addition, it is necessary to perform baking at a high temperature exceeding 200° C. at the time of forming the undercoat agent layer.

The present invention has been made in consideration of the above circumstances, and it is an object of the invention to provide an undercoat agent that has a large baking temperature margin at the time of forming an undercoat agent layer and enables formation of a film at low temperatures, and a method for producing a structure including a phase-separated structure using the undercoat agent.

In order to achieve the above-described object, the present invention employs the following configurations.

That is, a first aspect of the present invention is an undercoat agent that is used for subjecting a layer including a block copolymer to phase separation on a substrate, the undercoat agent containing a resin component (A1) having a constitutional unit (u1) represented by General Formula (u1) and a constitutional unit (u2) represented by

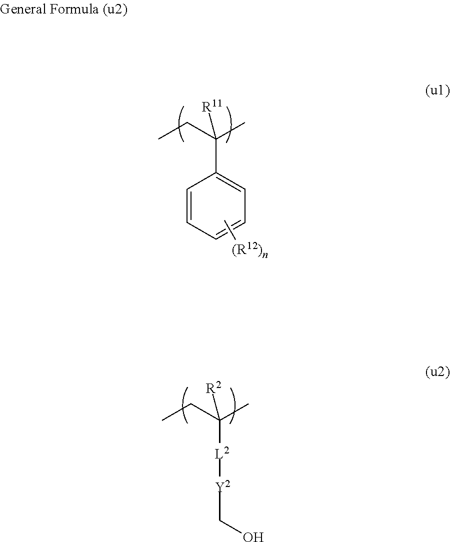

wherein, in General Formula (u1), R¹¹ represents a hydrogen atom, an alkyl group having 1 to 5 carbon atoms, or a halogenated alkyl group having 1 to 5 carbon atoms, R¹² represents a substituent, and n represents an integer of 1 to 5,

in General Formula (u2), R² represents a hydrogen atom, an alkyl group having 1 to 5 carbon atoms, or a halogenated alkyl group having 1 to 5 carbon atoms, L² represents a single bond or a divalent linking group, and Y² represents a divalent linking group having 5 to 15 carbon atoms.

A second aspect of the present invention is a method for producing a structure including a phase-separated structure, the method including: a step (i) of applying the undercoat agent according to the first aspect of the present invention on a substrate and forming an undercoat agent layer; a step (ii) of forming a layer including a block copolymer on the undercoat agent layer; and a step (iii) of subjecting the layer including a block copolymer to phase separation.

According to the present invention, an undercoat agent that has a large baking temperature margin at the time of forming an undercoat agent layer and enables formation of a film at low temperatures, and a method for producing a structure including a phase-separated structure using the undercoat agent, can be provided.

### BRIEF DESCRIPTION OF THE DRAWINGS

FIG. 1 is schematic process diagrams showing an embodiment of a method for producing a structure including a phase-separated structure.

FIG. 2 is a diagram showing an embodiment of an optional step.

FIG. 3 is a diagram schematically showing examples of structures including a phase-separated structure, which are produced by the method for producing a structure including a phase-separated structure according to the embodiment.

FIG. 4 is examples of overhead SEM photographs of structures including a phase-separated structure, which are produced by the method for producing a structure including a phase-separated structure according to the embodiment.

FIG. 5 is an example of an overhead SEM photograph of a phase-separated structure in a state in which horizontal cylinders and vertical cylinders are mixed.

### DETAILED DESCRIPTION OF THE INVENTION

In the present specification and the present claims, the term “aliphatic” is a relative concept used with respect to “aromatic” and is defined to mean a group, a compound, or the like that has no aromaticity.

Unless particularly specified otherwise, the term “alkyl group” is meant to include linear, branched, and cyclic monovalent saturated hydrocarbon groups.

Unless particularly specified otherwise, the term “alkylene group” is meant to include linear, branched, and cyclic divalent saturated hydrocarbon groups. The same applies to the alkyl group in an alkoxy group.

Examples of the “halogen atom” include a fluorine atom, a chlorine atom, a bromine atom, and an iodine atom.

A “halogenated alkyl group” is a group obtained by substituting some or all of the hydrogen atoms of an alkyl group with halogen atoms, and examples of the halogen atom include a fluorine atom, a chlorine atom, a bromine atom, and an iodine atom.

A “fluorinated alkyl group” or a “fluorinated alkylene group” is a group obtained by substituting some or all of the hydrogen atoms of an alkyl group or an alkylene group with fluorine atoms.

The term “constitutional unit” means a monomer unit (a monomeric unit) constituting a high-molecular weight compound (a resin, a polymer, or a copolymer).

The phrase “constitutional unit derived from” means a constitutional unit that is formed by cleavage of a multiple bond between carbon atoms, for example, an ethylenic double bond.

In an “acrylic acid ester”, a hydrogen atom bonded to the carbon atom at the α-position may be substituted with a substituent. The substituent (R^{αx}) that substitutes the hydrogen atom bonded to the carbon atom at the α-position is an atom or a group other than a hydrogen atom. In addition, an itaconic acid diester in which the substituent (R^{αx}) is substituted with a substituent having an ester bond, and an α-hydroxyacryl ester in which the substituent (R^{αx}) is substituted with a hydroxyalkyl group or a group obtained by modifying the hydroxy group of the hydroxyalkyl group, are also included in the acrylic acid ester. It is noted that unless particularly stated otherwise, a carbon atom at the α-position of the acrylic acid ester is a carbon atom to which the carbonyl group of acrylic acid is bonded.

Hereinafter, an acrylic acid ester in which a hydrogen atom bonded to the carbon atom at the α-position is substituted with a substituent, may be referred to as an α-substituted acrylic acid ester.

The term “derivative” is used as a concept that includes compounds in which a hydrogen atom at the α-position of the object compound has been substituted with another substituent such as an alkyl group or a halogenated alkyl group; and derivatives thereof. Examples of the derivatives thereof include a derivative in which the hydrogen atom of a hydroxy group of the object compound in which a hydrogen atom at the α-position may be substituted with a substituent is substituted with an organic group; and a derivative in which a substituent other than a hydroxy group is bonded to the object compound in which a hydrogen atom at the α-position may be substituted with a substituent. Unless particularly specified otherwise, the α-position refers to a first carbon atom adjacent to a functional group.

In a case where the phrase “may have a substituent” is described, both of a case where a hydrogen atom (—H) is substituted with a monovalent group, and a case where a methylene group (—CH₂—) is substituted with a divalent group, are included.

The term “exposure” is used as a general concept that includes irradiation with any form of radiation.

In the present specification and the present claims, depending on the structure represented by a chemical formula, asymmetric carbon atoms may be present, and enantiomers or diastereomers may be present. In that case, these isomers are represented by one chemical formula. These isomers may be used singly or may be used as mixtures.

### (Undercoat Agent)

An undercoat agent according to the first aspect of the present invention is an undercoat agent used subjecting a layer including a block copolymer to phase separation on a substrate. The undercoat agent of the present embodiment contains a resin component (A) having a constitutional unit (u1) represented by General Formula (u1) and a constitutional unit (u2) represented by General Formula (u2).

### <Block Copolymer>

The block copolymer is a high-molecular weight compound which has a plurality of kinds of partial constituent components (blocks) with constitutional units of the same kind being repeatedly bonded, and in which the plurality of kinds of blocks are bonded. The block copolymer according to the present embodiment is, for example, a high-molecular weight compound in which a hydrophobic polymer block (b11) and a hydrophilic polymer block (b21) are bonded. The hydrophobic polymer block (b11) (hereinafter, also simply referred to as “block (b11)”) refers to a block formed from a polymer (hydrophobic polymer) in which a plurality of monomers having relatively different affinities for water are used, and among the plurality of monomers, a monomer having a relatively lower affinity with water is polymerized. The hydrophilic polymer block (b21) (hereinafter, also simply referred to as “block (b21)”) refers to a block formed from a polymer (hydrophilic polymer) in which among the plurality of monomers, a monomer having a relatively higher affinity with water is polymerized.

The block (b11) and the block (b21) are not particularly limited as long as they form a combination that undergoes phase separation; however, a combination of blocks that are incompatible with each other is preferred.

In addition, it is preferable that the block (b11) and the block (b21) form a combination in which a phase formed of at least one kind of block among the plurality of kinds of blocks constituting the block copolymer can be more easily removed than a phase formed of other kinds of blocks.

The number of kinds of blocks constituting the block copolymer may be two or may be three or more.

In the block copolymer according to the present invention, partial constituent components (blocks) other than the block (b11) and the block (b21) may also be bonded.

Examples of the block (b11) or the block (b21) include a block in which a constitutional unit derived from styrene or a styrene derivative is repeatedly bonded, a block in which a constitutional unit derived from an acrylic acid ester which may have a hydrogen atom bonded to the carbon atom at the α-position substituted with a substituent (constitutional unit derived from an (α-substituted) acrylic acid ester) is repeatedly bonded, a block in which a constitutional unit derived from acrylic acid which may have a hydrogen atom bonded to the carbon atom at the α-position substituted with a substituent (constitutional unit derived from an (α-substituted) acrylic acid) is repeatedly bonded, a block in which a constitutional unit derived from a siloxane or a derivative thereof is repeatedly bonded, a block in which a constitutional unit derived from an alkylene oxide is repeatedly bonded, and a block in which a silsesquioxane structure-containing constitutional unit is repeatedly bonded.

Examples of the styrene derivative include compounds in which a hydrogen atom at the α-position of styrene has been substituted with a substituent such as an alkyl group or a halogenated alkyl group, and derivatives thereof. Examples of the derivatives thereof include compounds in which a substituent is bonded to the benzene ring of styrene which may have a hydrogen atom at the α-position substituted with a substituent. Examples of the above-described substituent include an alkyl group having 1 to 5 carbon atoms, a halogenated alkyl group having 1 to 5 carbon atoms, and a hydroxyalkyl group.

Specific examples of the styrene derivative include α-methylstyrene, 2-methylstyrene, 3-methylstyrene, 4-methylstyrene, 4-t-butylstyrene, 4-n-octylstyrene, and 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, and 4-vinylbenzyl chloride.

Examples of the (α-substituted) acrylic acid ester include an acrylic acid ester, and an acrylic acid ester in which a hydrogen atom bonded to the carbon atom at the α-position is substituted with a substituent. Examples of the above-described substituent include an alkyl group having 1 to 5 carbon atoms, a halogenated alkyl group having 1 to carbon atoms, and a hydroxyalkyl group.

Examples of the (α-substituted) acrylic acid ester include acrylic acid esters such as methyl acrylate, ethyl acrylate, propyl acrylate, n-butyl acrylate, t-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexylmethane acrylate, and propyltrimethoxysilane acrylate; and methacrylic acid esters such as methyl methacrylate, ethyl methacrylate, propyl methacrylate, n-butyl methacrylate, t-butyl methacrylate, cyclohexyl methacrylate, octyl methacrylate, nonyl methacrylate, hydroxyethyl methacrylate, hydroxypropyl methacrylate, benzyl methacrylate, anthracene methacrylate, glycidyl methacrylate, 3,4-epoxycyclohexylmethane methacrylate, and propyltrimethoxysilane methacrylate.

Examples of the (α-substituted) acrylic acid include acrylic acid, and an acrylic acid in which a hydrogen atom bonded to the carbon atom at the α-position is substituted with a substituent. Examples of the above-described substituent include an alkyl group having 1 to 5 carbon atoms, a halogenated alkyl group having 1 to 5 carbon atoms, and a hydroxyalkyl group.

Specific examples of the (α-substituted) acrylic acid include acrylic acid and methacrylic acid.

Examples of siloxane or derivatives thereof include dimethylsiloxane, diethylsiloxane, diphenylsiloxane, and methylphenylsiloxane.

Examples of the alkylene oxide include ethylene oxide, propylene oxide, isopropylene oxide, and butylene oxide.

The silsesquioxane structure-containing constitutional unit is preferably a cage-type silsesquioxane structure-containing constitutional unit. Examples of a monomer that provides the cage-type silsesquioxane structure-containing constitutional unit include a compound having a cage-type silsesquioxane structure and a polymerizable group.

Examples of the block copolymer according to the present embodiment include a high-molecular weight compound in which a block in which a constitutional unit derived from styrene or a styrene derivative is repeatedly bonded, and a block in which a constitutional unit derived from an (α-substituted) acrylic acid ester is repeatedly bonded, are bonded together; a high-molecular weight compound in which a block in which a constitutional unit derived from styrene or a styrene derivative is repeatedly bonded, and a block in which a constitutional unit derived from an (α-substituted) acrylic acid is repeatedly bonded, are bonded together; a high-molecular weight compound in which a block in which a constitutional unit derived from styrene or a styrene derivative is repeatedly bonded, and a block in which a constitutional unit derived from a siloxane or a derivative thereof is repeatedly bonded, are bonded together; a high-molecular weight compound in which a block in which a constitutional unit derived from an alkylene oxide is repeatedly bonded, and a block in which a constitutional unit derived from an (α-substituted) acrylic acid ester is repeatedly bonded, are bonded together; a high-molecular weight compound in which a block in which a constitutional unit derived from an alkylene oxide is repeatedly bonded, and a block in which a constitutional unit derived from an (α-substituted) acrylic acid is repeatedly bonded, are bonded together; a high-molecular weight compound in which a block in which a cage-type silsesquioxane structure-containing constitutional unit is repeatedly bonded, and a block in which a constitutional unit derived from an (α-substituted) acrylic acid ester is repeatedly bonded, are bonded together; a high-molecular weight compound in which a block in which a cage-type silsesquioxane structure-containing constitutional unit is repeatedly bonded, and a block in which a constitutional unit derived from an (α-substituted) acrylic acid is repeatedly bonded, are bonded together; and a high-molecular weight compound in which a block in which a cage-type silsesquioxane structure-containing constitutional unit is repeatedly bonded, and a block in which a constitutional unit derived from a siloxane or a derivative thereof is repeatedly bonded, are bonded together.

Among those described above, the block copolymer is preferably a high-molecular weight compound in which a block in which a constitutional unit derived from styrene or a styrene derivative is repeatedly bonded, and a block in which a constitutional unit derived from an (α-substituted) acrylic acid ester is repeatedly bonded, are bonded together, or a high-molecular weight compound in which a block in which a constitutional unit derived from styrene or a styrene derivative is repeatedly bonded, and a block in which a constitutional unit derived from an (α-substituted) acrylic acid is repeatedly bonded, are bonded together; more preferably a high-molecular weight compound in which a block in which a constitutional unit derived from styrene or a styrene derivative is repeatedly bonded, and a block in which a constitutional unit derived from an (α-substituted) acrylic acid ester is repeatedly bonded, are bonded together; and even more preferably a high-molecular weight compound in which a block in which a constitutional unit derived from styrene or a styrene derivative is repeatedly bonded, and a block in which a constitutional unit derived from a (meth)acrylic acid ester is repeatedly bonded, are bonded together.

Specifically, examples thereof include a polystyrene-polymethyl methacrylate (PS-PMMA) block copolymer, a polystyrene-polyethyl methacrylate block copolymer, a polystyrene-(poly-t-butyl methacrylate) block copolymer, a polystyrene-polymethacrylic acid block copolymer, and a polystyrene-polymethyl acrylate block copolymer, a polystyrene-polyethyl acrylate block copolymer, a polystyrene-(poly-t-butyl acrylate) block copolymer, and a polystyrene-polyacrylic acid block copolymer. Among these, a PS-PMMA block copolymer is particularly preferable.

The weight-average molecular weight (Mw) (based on the polystyrene-equivalent value determined by gel permeation chromatography) of each polymer constituting the block copolymer is not particularly limited as long as it has a size capable of inducing phase separation; however, the weight-average molecular weight

(Mw) is preferably 5,000 to 500,000, more preferably 5,000 to 400,000, and even more preferably 5,000 to 300,000.

The weight-average molecular weight (Mw) of the block copolymer is not particularly limited as long as it has a size capable of inducing phase separation; however, the weight-average molecular weight (Mw) is preferably 5,000 to 200,000, more preferably 20,000 to 150,000, and even more preferably 30,000 to 100,000.

The molecular weight dispersity (Mw/Mn) of the block copolymer is preferably 1.0 to 3.0, more preferably 1.0 to 1.5, and even more preferably 1.0 to 1.2. In addition, Mn represents the number average molecular weight.

The period of the block copolymer (length of one molecule of the block copolymer) is not particularly limited; however, the period is preferably 5 to 50 nm, more preferably 10 to 40 nm, and even more preferably 20 to 30 nm.

### <Resin Component (A1)>

The undercoat agent of the present embodiment contains a resin component (A) having a constitutional unit (u1) represented by General Formula (u1) and a constitutional unit (u2) represented by General Formula (u2).

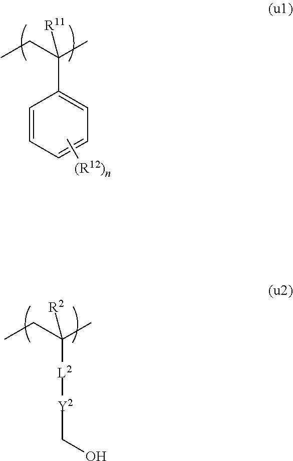

In General Formula (u1), R¹¹ represents a hydrogen atom, an alkyl group having 1 to 5 carbon atoms, or a halogenated alkyl group having 1 to 5 carbon atoms, R¹² represents a substituent, and n represents an integer of 1 to 5,

in General Formula (u2), R² represents a hydrogen atom, an alkyl group having 1 to 5 carbon atoms, or a halogenated alkyl group having 1 to 5 carbon atoms, L² represents a single bond or a divalent linking group, and Y² represents a divalent linking group having 5 to 15 carbon atoms.

«Constitutional Unit (u1)»

The constitutional unit (u1) is a constitutional unit represented by the above-described General Formula (u1).

In General Formula (u1), R¹¹ represents a hydrogen atom, an alkyl group having 1 to 5 carbon atoms, or a halogenated alkyl group having 1 to 5 carbon atoms.

The alkyl group having 1 to 5 carbon atoms for R¹¹ is preferably a linear or branched alkyl group having 1 to 5 carbon atoms. Specific examples thereof include a methyl group, an ethyl group, an n-propyl group, an isopropyl group, an n-butyl group, an isobutyl group, a tert-butyl group, a pentyl group, an isopentyl group, and a neopentyl group.

The halogenated alkyl group having 1 to 5 carbon atoms for R¹¹ is a group obtained by substituting some or all of the hydrogen atoms of the above-described alkyl group having 1 to 5 carbon atoms with halogen atoms. Examples of the halogen atom include a fluorine atom, a chlorine atom, a bromine atom and, an iodine atom, and a fluorine atom is preferred.

R¹¹ is more preferably a hydrogen atom or an alkyl group having 1 to 5 carbon atoms, even more preferably a hydrogen atom or a methyl group, and particularly preferably a hydrogen atom.

In General Formula (u1), R¹² represents a substituent. Examples of the substituent include a hydrocarbon group which may have a substituent, and a halogen atom. The hydrocarbon group preferably has 1 to 20 carbon atoms, and more preferably has 1 to 10 carbon atoms. Examples of the hydrocarbon group include a linear alkyl group which may have a substituent, a branched alkyl group which may have a substituent, a cyclic alkyl group which may have a substituent, and an aryl group which may have a substituent.

The alkyl group for R¹² is preferably an alkyl group having 1 to 10 carbon atoms, more preferably 1 to 8 carbon atoms, even more preferably 1 to 6 carbon atoms, and particularly preferably 1 to 3 carbon atoms. The alkyl group for R¹² is preferably a linear alkyl group or a branched alkyl group. Specific examples of the alkyl group for R¹² include a methyl group, an ethyl group, an n-propyl group, an isopropyl group, an n-butyl group, an isobutyl group, and a tert-butyl group.

The substituent for R¹² may be a partially or completely halogenated alkyl group (halogenated alkyl group), an alkylsilyl group in which some of the carbon atoms constituting the alkyl group have been substituted with silicon atoms or oxygen atoms, an alkylsilyloxy group, or an alkoxy group.

A partially halogenated alkyl group means an alkyl group in which some of the hydrogen atoms of the alkyl group have been substituted with halogen atoms. A completely halogenated alkyl group means an alkyl group in which all of the hydrogen atoms bonded to the alkyl group have been substituted with halogen atoms. Examples of the halogen atom include a fluorine atom, a chlorine atom, a bromine atom, and an iodine atom, and the halogen atom is preferably a fluorine atom, a chlorine atom, or a bromine atom, and more preferably a fluorine atom (that is, a fluorinated alkyl group is preferred).

Examples of the halogenated alkyl group for R¹² include groups in which some or all of the hydrogen atoms of the above-described alkyl group for R¹² have been substituted with halogen atoms. The halogen atom is preferably a fluorine atom. The halogenated alkyl group for R¹² preferably has 1 to 10 carbon atoms, more preferably 1 to 6 carbon atoms, and even more preferably 1 to 3 carbon atoms.

Examples of the alkylsilyl group include a trialkylsilyl group and a trialkylsilylalkyl group. Specific exemplary examples of the alkylsilyl group include a trimethylsilyl group, a trimethylsilylmethyl group, a trimethylsilylethyl group, and a trimethylsilyl-n-propyl group.

Examples of the alkylsilyloxy group include a trialkylsilyloxy group and a trialkylsilyloxyalkyl group. Specific exemplary examples of the alkylsilyloxy group include a trimethylsilyloxy group, a trimethylsilyloxymethyl group, a trimethylsilyloxyethyl group, and a trimethylsilyloxy-n-propyl group.

The alkoxy group preferably has 1 to 10 carbon atoms, more preferably 1 to 8 carbon atoms, even more preferably 1 to 6 carbon atoms, and particularly preferably 1 to 3 carbon atoms. The alkoxy group is preferably a linear alkoxy group or a branched alkoxy group. Examples of the alkoxy group include a methoxy group, an ethoxy group, an isopropoxy group, and a t-butoxy group.

The aryl group for R¹² preferably has 4 to 20 carbon atoms, more preferably 4 to 10 carbon atoms, and even more preferably 6 to 10 carbon atoms.

The hydrocarbon group for R¹² may have a substituent or does not have to have a substituent. Examples of the substituent that substitutes for a hydrogen atom of a hydrocarbon group include a halogen atom, a hydroxy group, a carbonyl group, and an amino group. Examples of the substituent that substitutes for a carbon atom chain of a hydrocarbon group include an oxygen atom, a silicon atom, and a carbonyl group.

Above all, R¹² is preferably a hydrocarbon group having 1 to 20 carbon atoms, which may include an oxygen atom, a halogen atom, or a silicon atom, since the layer including the block copolymer, which is formed on the undercoat agent layer, can undergo phase separation satisfactorily. R¹² is more preferably an alkyl group having 1 to 20 carbon atoms, which may include an oxygen atom or a halogen atom; even more preferably an alkyl group having 1 to 6 carbon atoms, a halogenated alkyl group having 1 to 6 carbon atoms, or an alkoxy group having 1 to 6 carbon atoms; and particularly preferably an alkyl group having 1 to 6 carbon atoms.

In General Formula (u1), n is an integer of 0 to 5, preferably an integer of 0 to 3, more preferably an integer of 0 to 2, even more preferably 0 or 1, and particularly preferably 0.

In General Formula (u1), the bonding position for R¹² in the benzene ring is preferably the ortho-position or the para-position, since the phase separation performance of the layer including the block copolymer is further enhanced.

Specific examples of the constitutional unit (u1) will be listed below but are not limited thereto. In the following formulae, R^{α} represents a hydrogen atom, a methyl group, or a trifluoromethyl group.

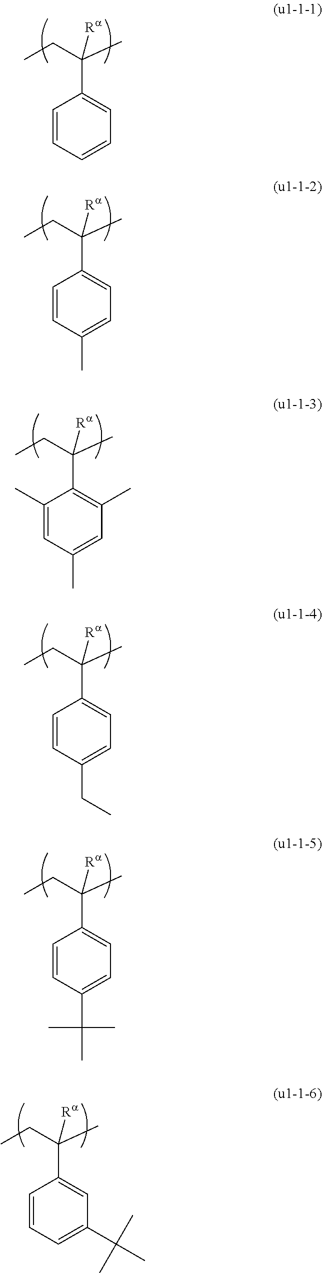

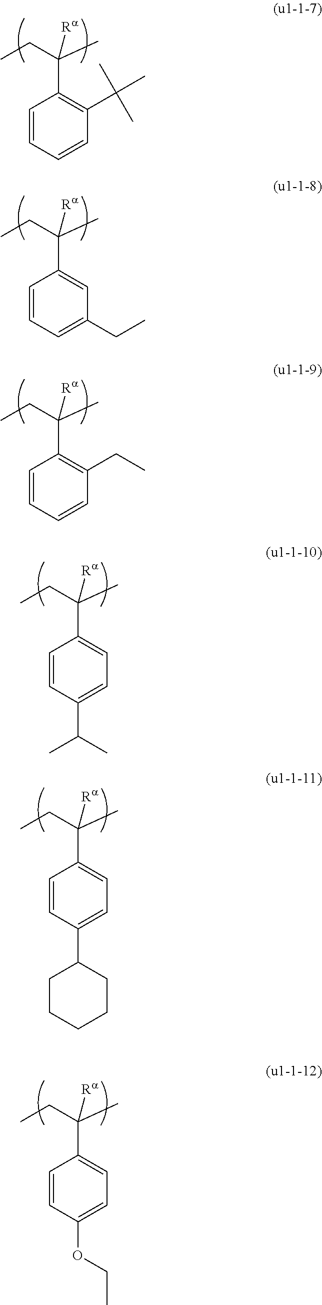

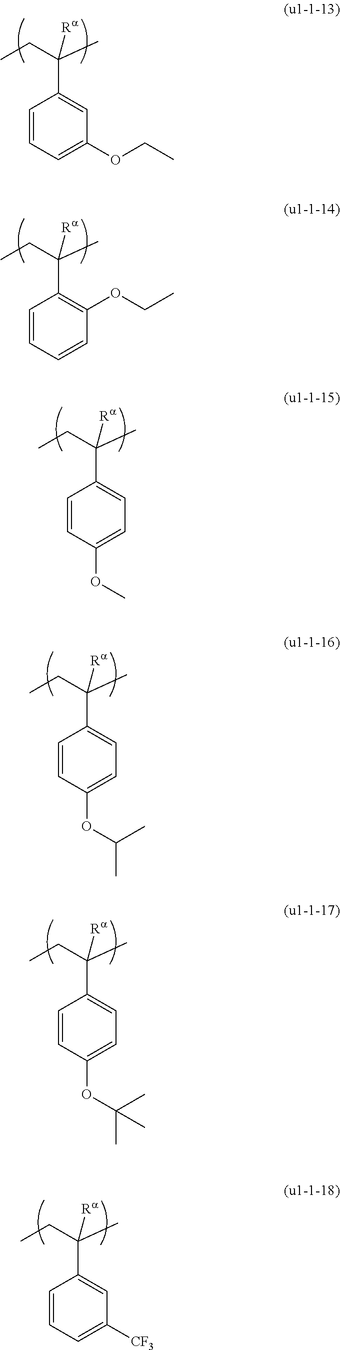

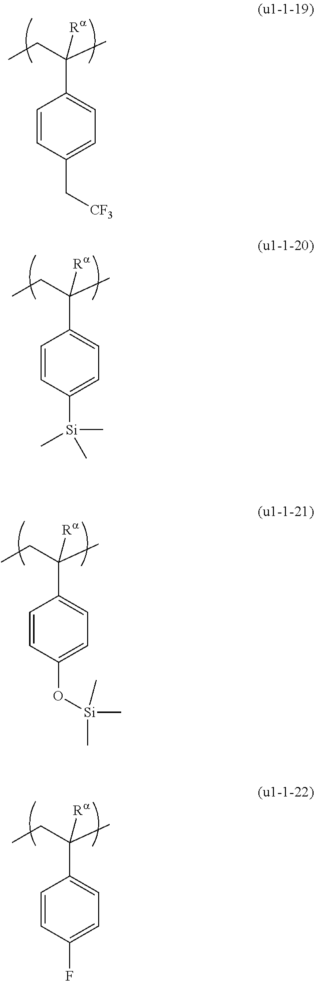

Regarding the constitutional unit (u1), one kind thereof may be used alone, or two or more kinds thereof may be used in combination.

The constitutional unit (u1) is preferably at least one constitutional unit selected from the group consisting of constitutional units represented by Chemical Formulae (u1-1-1) to (u1-1-22), more preferably at least one constitutional unit selected from the group consisting of constitutional units represented by Chemical Formulae (u1-1-1) to (u1-1-17), even more preferably at least one constitutional unit selected from the group consisting of constitutional units represented by Chemical Formulae (u1-1-1) to (u1-1-11), and particularly preferably at least one constitutional unit selected from the group consisting of constitutional units represented by Chemical Formulae (u1-1-1) to (u1-1-3).

The proportion of the constitutional unit (u1) in the component (A1) may be 90.0 mol % to 99.9 mol % with respect to the total amount of all the constitutional units constituting the component (A1). The proportion of the constitutional unit (u1) is preferably 95.0 mol % to 99.9 mol %, more preferably 96.0 mol % to 99.9 mol %, even more preferably 97.0 mol % to 99.9 mol %, and particularly preferably 98.0 mol % to 99.9 20 mol %, with respect to the total amount of all the constitutional units constituting the component (A1). The upper limit value of the proportion of the constitutional unit (u1) in the component (A1) may be 99.5 mol % or less, may be 99.3 mol % or less, or may be 99.0 mol % or less, with respect to the total amount of all the constitutional units constituting the component (A1).

When the proportion of the constitutional unit (u1) is within the above-described preferable range, the baking temperature margin for the film formation of the undercoat agent layer is likely to increase, and the layer including the block copolymer to be formed on the undercoat agent layer can satisfactorily undergo phase separation even when baked at low temperatures (about 150° C. to 200° C.).

«Constitutional Unit (u2)»

The constitutional unit (u2) is a constitutional unit represented by the above-described General Formula (u2).

In General Formula (u2), R² represents a hydrogen atom, an alkyl group having 1 to 5 carbon atoms, or a halogenated alkyl group having 1 to 5 carbon atoms. R² is similar to R¹¹ in the constitutional unit (u1).

R² is more preferably a hydrogen atom or an alkyl group having 1 to 5 carbon atoms, even more preferably a hydrogen atom or a methyl group, and particularly preferably a hydrogen atom.

In General Formula (u2), L² represents a single bond or a divalent linking group. Suitable examples of the divalent linking group for L² include a divalent hydrocarbon group which may have a substituent, and a divalent linking group including a hetero atom.
Divalent Hydrocarbon Group Which May Have Substituent:

When L² is a divalent hydrocarbon group which may have a substituent, the hydrocarbon group may be an aliphatic hydrocarbon group or an aromatic hydrocarbon group.
Aliphatic Hydrocarbon Group for L²

An aliphatic hydrocarbon group means a hydrocarbon group that has no aromaticity. The aliphatic hydrocarbon group may be saturated or unsaturated, and usually, it is preferable that the aliphatic hydrocarbon group is saturated.

Examples of the aliphatic hydrocarbon group include a linear or branched aliphatic hydrocarbon group, and an aliphatic hydrocarbon group including a ring in the structure.
Linear or Branched Aliphatic Hydrocarbon Group

This linear aliphatic hydrocarbon group preferably has 1 to 10 carbon atoms, more preferably 1 to 6 carbon atoms, even more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

This branched aliphatic hydrocarbon group preferably has 2 to 10 carbon atoms, more preferably 3 to 6 carbon atoms, even more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH ₃)CH(CH ₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH ₂ CH(CH ₃)CH₂—; and alkyltetramethylene groups such as —CH(CH₃)CH₂CH₂CH₂— and —CH₂CH(CH₃)CH₂CH₂—. The alkyl group of the alkylalkylene group is preferably a linear alkyl group having 1 to 5 carbon atoms.

The linear or branched aliphatic hydrocarbon group may have a substituent or does not have to have a substituent. Examples of this substituent include a fluorine atom, a fluorinated alkyl group having 1 to 5 carbon atoms and substituted with a fluorine atom, and a carbonyl group.
Aliphatic Hydrocarbon Group Including Ring in Structure

Examples of the aliphatic hydrocarbon group including a ring in the structure include a cyclic aliphatic hydrocarbon group which may include a substituent including a hetero atom in the ring structure (a group obtained by eliminating two hydrogen atoms from an aliphatic hydrocarbon ring), a group in which the cyclic aliphatic hydrocarbon group is bonded to the terminals of a linear or branched aliphatic hydrocarbon group, and a group in which the cyclic aliphatic hydrocarbon group is intercalated into a linear or branched aliphatic hydrocarbon group. Examples of the linear or branched aliphatic hydrocarbon group include groups similar to those described above.

The cyclic aliphatic hydrocarbon group preferably has 3 to 20 carbon atoms, and more preferably 3 to 12 carbon atoms.

The cyclic aliphatic hydrocarbon group may be a polycyclic group or a monocyclic group. The monocyclic alicyclic hydrocarbon group is preferably a group obtained by eliminating two hydrogen atoms from a monocycloalkane. This monocycloalkane preferably has 3 to 6 carbon atoms, and specific examples thereof include cyclopentane and cyclohexane. The polycyclic alicyclic hydrocarbon group is preferably a group obtained by eliminating two hydrogen atoms from a polycycloalkane, this polycycloalkane preferably has 7 to 12 carbon atoms, and specific examples thereof include adamantane, norbornane, isobornane, tricyclodecane, and tetracyclododecane.

The cyclic aliphatic hydrocarbon group may have a substituent or does not have to have a substituent. Examples of the substituent include an alkyl group, an alkoxy group, a halogen atom, a halogenated alkyl group, a hydroxy group, and a carbonyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms; more preferably a methoxy group, an ethoxy group, an n-propoxy group, an isopropoxy group, an n-butoxy group, or a tert-butoxy group; and even more preferably a methoxy group or an ethoxy group.

The halogen atom as the substituent is preferably a fluorine atom.

Examples of the halogenated alkyl group as the substituent include groups in which some or all of the hydrogen atoms in the above-described alkyl group have been substituted with the above-described halogen atoms.

In the cyclic aliphatic hydrocarbon group, some of the carbon atoms constituting the ring structure thereof may be substituted with a substituent including a hetero atom. This substituent including a hetero atom is preferably —O—, —C(═O)—O—, —S—, —S(═O)₂—, or —S(═0)₂—O—.
Aromatic Hydrocarbon Group for L²

The aromatic hydrocarbon group is a hydrocarbon group having at least one aromatic ring.

This aromatic ring is not particularly limited as long as it is a cyclic conjugated system having (4n +2) units of 7C electrons and may be monocyclic or polycyclic. The aromatic ring preferably has 5 to 30 carbon atoms, more preferably 5 to 20 carbon atoms, even more preferably 6 to 15 carbon atoms, and particularly preferably 6 to 12 carbon atoms. However, it should be noted that the number of carbon atoms of the aromatic ring does not include the number of carbon atoms of the substituent.

Specific examples of the aromatic ring include aromatic hydrocarbon rings such as benzene, naphthalene, anthracene, and phenanthrene; and aromatic heterocyclic rings obtained by substituting some of the carbon atoms constituting the above-described aromatic hydrocarbon rings with hetero atoms. Examples of the hetero atom for the aromatic heterocyclic ring include an oxygen atom, a sulfur atom, and a nitrogen atom. Specific examples of the aromatic heterocyclic ring include a pyridine ring and a thiophene ring.

Specific examples of the aromatic hydrocarbon group include a group obtained by eliminating two hydrogen atoms from the above-described aromatic hydrocarbon ring or aromatic heterocyclic ring (an arylene group or a heteroarylene group); a group obtained by eliminating two hydrogen atoms from an aromatic compound having two or more aromatic rings (for example, biphenyl or fluorene); and a group in which one hydrogen atom of a group obtained by eliminating one hydrogen atom from the above-described aromatic hydrocarbon ring or aromatic heterocyclic ring (an aryl group or a heteroaryl group) has been substituted with an alkylene group (for example, a group obtained by further eliminating one hydrogen atom from the aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aryl group or the heteroaryl group preferably has 1 to 4 carbon atoms, more preferably 1 or 2 carbon atoms, and particularly preferably 1 carbon atom.

In the aromatic hydrocarbon group, the hydrogen atom contained in the aromatic hydrocarbon group may be substituted with a substituent. For example, a hydrogen atom bonded to the aromatic ring in the aromatic hydrocarbon group may be substituted with a substituent. Examples of the substituent include an alkyl group, an alkoxy group, a halogen atom, a halogenated alkyl group, and a hydroxy group.

The alkyl group as the substituent is preferably an alkyl group having 1 to 5 carbon atoms, and more preferably a methyl group, an ethyl group, a propyl group, an n-butyl group, or a tert-butyl group.

Examples of the alkoxy group, the halogen atom, and the halogenated alkyl group as the substituent include the exemplary examples described above as the substituent that substitutes for a hydrogen atom contained in the cyclic aliphatic hydrocarbon group.
Divalent Linking Group Including Hetero Atom

When L² is a divalent linking group including a hetero atom, preferred examples of the linking group include —O—, —C(═O)—O—, —O—C(═O)—, —C(═O)—, —O—C(═O)—O—, —C(═O)—NH—, —NH—, —NH—C(═NH)—(in which H may be substituted with a substituent such as an alkyl group or an acyl group), —S—, —S(═O)2—, —S(═O)₂—O—, and a group represented by General Formula —Y¹¹—O—Y¹²—, —Y¹¹—O—, —Y¹¹—C(═O)—O—, —C(═O)—O—Y¹¹, —[Y¹¹—C(═O)—O]_{m″}—Y¹²—, —Y¹¹—O—C(═O)—Y¹²— or —Y¹¹—S(═O)₂—O—Y¹²— [in the formulae, Y¹¹ and Y¹² each independently represent a divalent hydrocarbon group which may have a substituent, O represents an oxygen atom, and m″ represents an integer of 0 to 3].

When the divalent linking group including a hetero atom is —C(═O)—NH—, —C(═O)—NH—C(═O—, —NH—, or —NH—C(═NH)—, H may be substituted with a substituent such as an alkyl group or an acyl group. The substituent (an alkyl group, an acyl group, or the like) preferably has 1 to 10 carbon atoms, more preferably 1 to 8 carbon atoms, and particularly preferably 1 to 5 carbon atoms.

In General Formulae —Y¹¹—O—Y¹²—, —Y¹¹—O—, —Y¹¹—C(═O)—O—, —C(═O)—O—Y¹¹, —[Y¹¹—C(═O)—O]_{m″}—Y¹²—, —Y¹¹—O—C(═O)—Y¹²— and —Y¹¹—S(═O)₂—O—Y¹²—, Y¹¹, and Y¹² each independently represent a divalent hydrocarbon group which may have a substituent. Examples of the divalent hydrocarbon group include groups similar to the examples of the above-described divalent hydrocarbon group which may have a substituent.

Y¹¹ is preferably a linear aliphatic hydrocarbon group, more preferably a linear alkylene group, even more preferably a linear alkylene group having 1 to 5 carbon atoms, and particularly preferably a methylene group or an ethylene group.

Y¹² is preferably a linear or branched aliphatic hydrocarbon group, and more preferably a methylene group, an ethylene group, or an alkylmethylene group. The alkyl group of the alkylmethylene group is preferably a linear alkyl group having 1 to 5 carbon atoms, more preferably a linear alkyl group having 1 to 3 carbon atoms, and most preferably a methyl group.

In the group represented by Formula y12_{—} , m″ represents an integer of 0 to 3, preferably an integer of 0 to 2, more preferably 0 or 1, and particularly preferably 1. In other words, the group represented by Formula: —[Y¹¹—C(═))—O)]_{m″}—Y¹²— is particularly preferably a group represented by Formula —Y¹¹ —C(═O)—O—Y¹²—. Above all, a group represented by Formula —(CH₂)_{a′}—C(═O)—O—(CH₂)_{b}′— is preferable. In the

Formula, a′ is an integer of 1 to 10, preferably an integer of 1 to 8, more preferably an integer of 1 to 5, even more preferably 1 or 2, and most preferably 1. b′ is an integer of 1 to 10, preferably an integer of 1 to 8, more preferably an integer of 1 to 5, even more preferably 1 or 2, and most preferably 1.

As L^{2 ,} a single bond, an ester bond [—C(═O)—O—], an ether bond (—O—), a linear or branched alkylene group, or a combination of two or more of these is preferable.

In General Formula (u2), Y² represents a divalent linking group having 5 to 15 carbon atoms. Examples of the divalent linking group for Y² include a divalent hydrocarbon group which may have a substituent.

The divalent hydrocarbon group which may have substituent for Y² preferably has 5 to 11 carbon atoms, more preferably 5 to 10 carbon atoms, even more preferably 5 to 8 carbon atoms, and particularly preferably 5 to 7 carbon atoms.

Examples of the divalent hydrocarbon group which may have a substituent for Y² include groups similar to the examples of the above-described divalent hydrocarbon group which may have a substituent for L^{2 .} The divalent hydrocarbon group which may have a substituent for Y^{2 ,} may be an aliphatic hydrocarbon group or may be an aromatic hydrocarbon group.

The aliphatic hydrocarbon group for Y² may be a linear or branched aliphatic hydrocarbon group or may be an aliphatic hydrocarbon group including a ring in the structure. The aliphatic hydrocarbon group represented by Y² may be saturated or unsaturated; however, the aliphatic hydrocarbon group is preferably saturated.

The linear or branched aliphatic hydrocarbon group for Y² has 5 to 15 carbon atoms, preferably 5 to 12 carbon atoms, more preferably 5 to 11 carbon atoms, even more preferably 5 to 10 carbon atoms, and particularly preferably 5 to 8 carbon atoms. The linear or branched aliphatic hydrocarbon group for Y² is preferably a linear or branched alkylene group which may have a substituent.

The linear or branched aliphatic hydrocarbon group may have a substituent or does not have to have a substituent. Examples of this substituent include a fluorine atom, a fluorinated alkyl group having 1 to 5 carbon atoms and substituted with a fluorine atom, and a carbonyl group.

The substituent may substitute for a methylene group (—CH₂—) constituting the hydrocarbon chain of an aliphatic hydrocarbon group. Examples of the substituent that substitutes for a methylene group (—CH₂—) include —O—, —C(═O)—O—, —O—C(═O)—, —C(═O)—, —O—C(═O)—O—, —C(═O)—NR′—, —NR′—, and —NR′—C(═NR′)— (in which R′ represents a hydrogen atom, an alkyl group having 1 to 3 carbon atoms, or an acyl group having 1 to 3 carbon atoms), —S—, —S(═O)₂—, and —S(═O)₂—O—.

Above all, the substituent that substitutes for the methylene group (—CH₂—) is preferably an oxygen atom (—O—). Examples of the aliphatic hydrocarbon group in which a methylene group (—CH₂—) is substituted with an oxygen atom include an oxyalkylene group.

The number of substituents that substitute for the aliphatic hydrocarbon group methylene group (—CH₂—) for Y² is preferably 0 to 3, more preferably 0 to 2, and even more preferably 0 or 1.

The aliphatic hydrocarbon group including a ring in the structure, for Y^{2 ,} has 5 to 15 carbon atoms, preferably 5 to 12 carbon atoms, and more preferably 5 to 11 carbon atoms. Examples of the aliphatic hydrocarbon group including a ring in the structure include a cyclic aliphatic hydrocarbon group (a group obtained by eliminating two hydrogen atoms from an aliphatic hydrocarbon ring); a group in which a cyclic aliphatic hydrocarbon group is bonded to a terminal of a linear or branched aliphatic hydrocarbon group which may have a substituent; and a group in which a cyclic aliphatic hydrocarbon group is intercalated into a linear or branched aliphatic hydrocarbon group which may have a substituent. Examples of the linear or branched aliphatic hydrocarbon group which may have a substituent, which is bonded to the cyclic aliphatic hydrocarbon group, include a linear or branched alkylene group which may have a substituent, and a linear or branched alkylene group or a linear or branched oxyalkylene group is preferable.

The cyclic aliphatic hydrocarbon group may be a polycyclic group or a monocyclic group. The monocyclic alicyclic hydrocarbon group is preferably a group obtained by eliminating two hydrogen atoms from a monocycloalkane. The monocycloalkane preferably has 5 to 8 carbon atoms, and specific examples thereof include cyclopentane and cyclohexane. The polycyclic alicyclic hydrocarbon group is preferably a group obtained by eliminating two hydrogen atoms from a polycycloalkane. The polycycloalkane preferably has 7 to 12 carbon atoms, and specific examples include adamantane, norbornane, isobornane, tricyclodecane, and tetracyclododecane.

The cyclic aliphatic hydrocarbon group may have a substituent or does not have to have a substituent. Examples of the substituent include an alkyl group, an alkoxy group, a halogen atom, a halogenated alkyl group, a hydroxy group, and a carbonyl group.

In the cyclic aliphatic hydrocarbon group, some of the carbon atoms constituting the ring structure thereof may be substituted with a substituent including a hetero atom. This substituent including a hetero atom is preferably —O—, —C(═O)—O—, —S—, —S(═O)₂—, or —S(═O)₂—O—.

The aromatic hydrocarbon group for Y² may be monocyclic or may be polycyclic. The aromatic ring preferably has 5 to 15 carbon atoms, more preferably 6 to 12 carbon atoms, even more preferably 6 to 10 carbon atoms, and particularly preferably has 6 to 12 carbon atoms.

The aromatic ring may be an aromatic hydrocarbon ring such as benzene, naphthalene, anthracene, or phenanthrene, or may be an aromatic heterocyclic ring. Examples of the hetero atom for the aromatic heterocyclic ring include an oxygen atom, a sulfur atom, and a nitrogen atom. Specific examples of the aromatic heterocyclic ring include a pyridine ring and a thiophene ring.

Examples of the aromatic hydrocarbon group include a group obtained by eliminating two hydrogen atoms from an aromatic hydrocarbon ring or an aromatic heterocyclic ring (an arylene group or a heteroarylene group); a group obtained by eliminating two hydrogen atoms from an aromatic compound including two or more aromatic rings; and a group in which one hydrogen atom of a group obtained by eliminating one hydrogen atom from an aromatic hydrocarbon ring or an aromatic heterocyclic ring (an aryl group or a heteroaryl group) has been substituted with an alkylene group or an oxyalkylene group. The alkylene group or oxyalkylene group that is bonded to the aryl group or heteroaryl group preferably has 1 to 4 carbon atoms, more preferably has 1 or 2 carbon atoms, and particularly preferably has 1 carbon atom.

With regard to the aromatic hydrocarbon group, a hydrogen atom contained in the aromatic hydrocarbon group may be substituted with a substituent. Examples of the substituent include an alkyl group, an alkoxy group, a halogen atom, and a halogenated alkyl group. The number of carbon atoms in the alkyl group, the alkoxy group, and the halogenated alkyl group as the substituent is preferably 1 to 5, more preferably 1 to 3, and even more preferably 1 or 2.

Y² is preferably a linear or branched aliphatic hydrocarbon group which may have a substituent, or an aromatic hydrocarbon group which may have a substituent; more preferably a linear or branched alkylene group which may have a substituent, or an aromatic hydrocarbon group which may have a substituent; even more preferably a linear alkylene group, a linear oxyalkylene group, or an aromatic hydrocarbon group which may have a substituent; and particularly preferably a linear alkylene group, or an aromatic hydrocarbon group which may have a substituent.

The constitutional unit (u2) is preferably a constitutional unit represented by General Formula (u2-1).

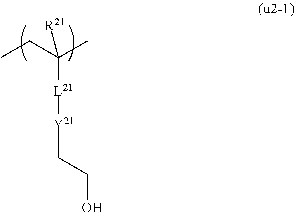

In the formula, R²¹ represents a hydrogen atom, an alkyl group having 1 to 5 carbon atoms, or a halogenated alkyl group having 1 to 5 carbon atoms; L² ‘ represents a single bond or a divalent linking group; and Y² ’ represents a divalent linking group having 4 to 14 carbon atoms.

In General Formula (u2-1), R²¹ represents a hydrogen atom, an alkyl group having 1 to 5 carbon atoms, or a halogenated alkyl group having 1 to 5 carbon atoms. R²¹ is similar to R² in General Formula (u2).

In General Formula (u2-1), L²¹ represents a single bond or a divalent linking group. L²¹ is similar to L² in General Formula (u2).

In General Formula (u2-1), y21 represents a divalent linking group having 4 to 14 carbon atoms. Suitable examples of Y²¹ include a divalent hydrocarbon group having 4 to 14 carbon atoms, which may have a substituent. The divalent hydrocarbon group which may have a substituent for Y²¹ preferably has 4 to 10 carbon atoms, more preferably 4 to 9 carbon atoms, even more preferably 4 to 7 carbon atoms, and particularly preferably 4 to 6 carbon atoms.

Examples of Y²¹ include those similar to the examples of Y² in General Formula (u2). However, it is preferable that the number of carbon atoms is obtained by subtracting one from the number of carbon atoms mentioned for Y^{2 .}

Y²¹ is preferably a linear or branched aliphatic hydrocarbon group which may have a substituent, or an aromatic hydrocarbon group which may have a substituent; more preferably a linear or branched alkylene group which may have a substituent, or an aromatic hydrocarbon group which may have a substituent; even more preferably a linear alkylene group, a linear oxyalkylene group, or an aromatic hydrocarbon group which may have a substituent; and still more preferably a linear alkylene group, or an aromatic hydrocarbon group which may have a substituent.

Specific examples of the constitutional unit (u2) will be listed below; however, the examples are not limited thereto. In the following formulae, R^{α} represents a hydrogen atom, a methyl group, or a trifluoromethyl group.

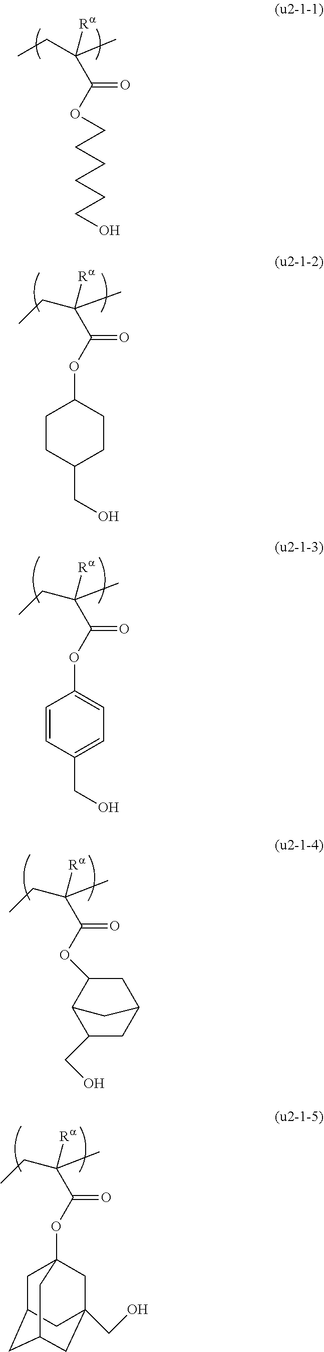

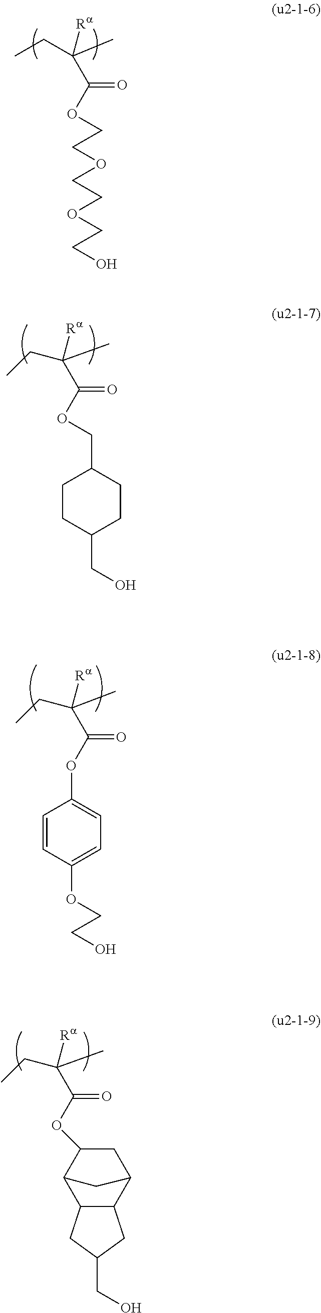

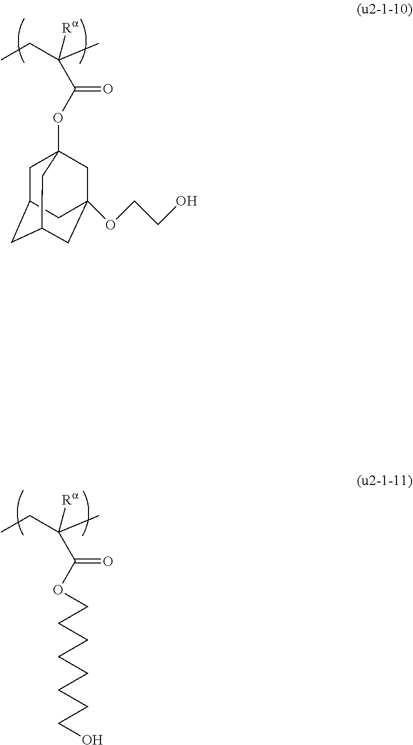

Regarding the constitutional unit (u2), one kind thereof may be used alone, or two or more kinds thereof may be used in combination.

The constitutional unit (u2) is preferably at least one constitutional unit selected from the group consisting of constitutional units represented by Chemical Formulae (u2-1-1) to (u2-1-11); more preferably at least one constitutional unit selected from the group consisting of constitutional units represented by Chemical Formulae (u2-1-1) to (u2-1-6); and even more preferably at least one constitutional unit selected from the group consisting of constitutional units represented by Chemical Formulae (u2-1-1) to (u2-1-3).

The proportion of the constitutional unit (u2) in the component (A1) may be 0.1 mol % to 10.0 mol % with respect to the total amount of all the constitutional units constituting the component (A1). The proportion of the constitutional unit (u2) is preferably 0.1 mol % to 5.0 mol %, more preferably 0.1 mol % to 4.0 mol %, even more preferably 0.1 mol % to 3.0 mol %, and particularly preferably 0.1 mol % to 2.0 mol %, with respect to the total amount of all the constitutional units constituting the component (A1). The lower limit value of the proportion of the constitutional unit (u2) in the component (A1) may be 0.5 mol % or more, may be 0.7 mol % or more, or may be 1.0 mol % or more, with respect to the total amount of all the constitutional units constituting the component (A1).

When the proportion of the constitutional unit (u2) is within the above-described preferred range, the baking temperature margin for the film formation of the undercoat agent layer is likely to increase, and the layer including the block copolymer to be formed on the undercoat agent layer can satisfactorily undergo phase separation even when baked at low temperatures (about 150° C. to 200° C.).

### «Optional Constitutional Unit»

The component (A1) may have an optional constitutional unit (constitutional unit (u3)), in addition to the constitutional unit (u1) and the constitutional unit (u2), to the extent that does not impair the effect of the present invention. Examples of the constitutional unit (u3) include a constitutional unit derived from a monomer copolymerizable with monomers from which the constitutional unit (u1) and the constitutional unit (u2) are derived.

When the component (A1) has the constitutional unit (u3), the proportion of the constitutional unit (u3) in the component (A1) is preferably more than 0 mol % and less than 5.0 mol %, more preferably more than 0 mol % and 3.0 mol % or less, even more preferably more than 0 mol % and 2.0 mol % or less, and particularly preferably more than 10 0 mol % and 1.0 mol % or less, with respect to the total amount of all the constitutional units constituting the component (A1).

The weight-average molecular weight (Mw) (based on the polystyrene-equivalent value determined by gel permeation chromatography (GPC)) of the component (A1) is not particularly limited, and the weight-average molecular weight (Mw) is preferably 1,000 to 200,000, more preferably 1,500 to 200,000, and even more preferably 2,000 to 150,000.

When the weight-average molecular weight (Mw) is equal to or less than the upper limit value of this preferred range, since the component (A1) dissolves sufficiently in the organic solvent that will be described below, the coatability on the substrate is excellent. On the other hand, when the weight-average molecular weight is equal to or larger than the lower limit value of this preferred range, the production stability of the high-molecular weight compound is excellent, and an undercoat agent composition having excellent coatability on a substrate is obtained.

The molecular weight dispersity (Mw/Mn) of the component (A1) is not particularly limited, and is preferably 1.0 to 5.0, more preferably 1.0 to 3.0, and even more preferably 1.0 to 2.5. In addition, Mn represents the number average molecular weight.

The component (A1) can be obtained by polymerizing each of the monomers from which the constitutional units are derived, by performing known radical polymerization or the like using, for example, a radical polymerization initiator such as azobisisobutyronitrile (AIBN). In addition, for the component (A1), for example, an initiator such as CH₃—CH₂—CH(CH₃)—Li may be used during the polymerization.

Furthermore, for the component (A1), for example, a terminal modifier such as isobutylene sulfide may also be used during the polymerization.

Regarding the monomer from which each constitutional unit is derived, a commercially available monomer may be used, or a monomer synthesized by utilizing a known method may be used.

Regarding the component (A1), one kind thereof may be used alone, or two or more kinds thereof may be used in combination.

In the undercoat agent of the present embodiment, the content of the component (A1) may be appropriately adjusted according to the desired film thickness of the undercoat agent layer, or the like. In the undercoat agent composition of the present embodiment, the content of the component (A1) is preferably 70% by mass or more, more preferably 90% by mass or more, and even more preferably 95% by mass or more, with respect to the total solid content.

### <Optional Components>

The undercoat agent of the present embodiment may further contain other components (optional components) in addition to the above-mentioned component (A1).

### «Acid Generator Component (B)»

The undercoat agent of the present embodiment may contain an acid generator component (B) (hereinafter, also referred to as a “component (B)”). The component (B) generates acid by being heated and exposed. The component (B) does not need to have acidity per se and may be any compound that is decomposed by heat, light, or the like and functions as an acid.

The component (B) is not particularly limited, and an acid generator component for a chemically amplified resist, which has been hitherto used in photolithography, can be used.

Examples of such an acid generator component include a thermal acid generator that generates acid by heating, and a photoacid generator that generates acid by exposure. For example, various kinds of acid generators are known, including onium salt-based acid generators such as iodonium salts and sulfonium salts; oxime sulfonate-based acid generators; diazomethane-based acid generators such as bisalkyl or bisaryl sulfonyl diazomethane and poly(bis-sulfonyl)diazomethane; nitrobenzyl sulfonate-based acid generators; iminosulfonate-based acid generators; and disulfone-based acid generators.

Here, the term “thermal acid generator that generates acid by heating” specifically means a component that generates acid by heating at 200° C. or lower. When the heating temperature is 200° C. or lower, the generation of acid can be easily controlled. Preferably, a component that generates acid by heating at 50° C. to 150° C. is used. When the heating temperature is preferably 50° C. or higher, the stability in the undercoat agent is improved.

Regarding the onium salt-based acid generators of the component (B), compounds having at least one anion group selected from the group consisting of a sulfonate anion, a carboxylate anion, a sulfonylimide anion, a bis(alkylsulfonyl)imide anion, a tris(alkylsulfonyl)methide anion, and a fluorinated antimonate ion, as the anion part, are preferred.

In the undercoat agent of the present embodiment, for the component (B), one kind of acid generator may be used alone, or two or more kinds of acid generators may be used in combination.

When the undercoat agent contains the component (B), the content of the component (B) in the undercoat agent is preferably 0.5 to 30 parts by mass, and more preferably 1 to 20 parts by mass, with respect to 100 parts by mass of the component (A1).

The undercoat agent of the present embodiment can further contain miscible additives appropriately as desired, for example, an additive resin for ameliorating the performance of the undercoat agent layer, a surfactant for improving coatability, a dissolution inhibitor, a plasticizer, a stabilizer, a colorant, a halation preventing agent, a dye, a sensitizer, a base multiplier, and a basic compound (a nitrogen-containing compound such as imidazole, or the like), to the extent that does not impair the effects of the present invention.

### «Organic Solvent (S)»

The undercoat agent of the present embodiment can be produced by dissolving the component (A1) and if necessary, optional components such as the component (B) in an organic solvent (hereinafter, also referred to as “component (S)”).

The component (S) may be any organic solvent that can dissolve each component to be used and form a uniform solution, and any one kind or two or more kinds can be selected as appropriate from the organic solvents that are conventionally known as solvents for film compositions including a resin as a main component, and used.

Exemplary examples of the component (S) include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; derivatives of polyhydric alcohols, such as compounds having an ester bond such as ethylene glycol monoacetate, diethylene glycol monoacetate, propylene glycol monoacetate, and dipropylene glycol monoacetate; compounds having an ether bond such as monoalkyl ethers such as monomethyl ether, monoethyl ether, monopropyl ether, and monobutyl ether, or monophenyl ether, of the above-described polyhydric alcohols or compounds having an ester bond [among these, propylene glycol monomethyl ether acetate (PGMEA) and propylene glycol monomethyl ether (PGME) are preferred]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene, and mesitylene.

The component (S) may be used singly or may be used as a mixed solvent of two or more kinds thereof.

Among these, as the component (S), propylene glycol monomethyl ether acetate (PGMEA), propylene glycol monomethyl ether (PGME), cyclohexanone, and EL are preferable.

In addition, a mixed solvent obtained by mixing PGMEA with a polar solvent is also preferable. The blending ratio (mass ratio) of the mixed solvent may be appropriately determined while taking into consideration the compatibility of the PGMEA with the polar solvent; however, the blending ratio is considered to be preferably in the range of 1:9 to 9:1, and more preferably in the range of 2:8 to 8:2. For example, when EL is blended as the polar solvent, the mass ratio of PGMEA:EL is preferably 1:9 to 9:1, and more preferably 2:8 to 8:2. In addition, when PGME is blended as the polar solvent, the mass ratio of PGMEA:PGME is preferably 1:9 to 9:1, more preferably 2:8 to 8:2, and even more preferably 3:7 to 7:3. In addition, when PGME and cyclohexanone are blended as the polar solvent, the mass ratio of PGMEA:(PGME +cyclohexanone) is preferably 1:9 to 9:1, more preferably 2:8 to 8:2, and even more preferably 3:7 to 7:3.

As the component (S), PGMEA, EL, or the mixed solvent of PGMEA and a polar solvent, and a mixed solvent with y-butyrolactone are also preferable. In this case, as the mixing proportion, the mass ratio between the former and the latter is preferably set to 70:30 to 95:5.

The amount of use of the component (S) is not particularly limited and is appropriately set according to the coating film thickness, at a concentration at which the component (S) can be applied on a substrate or the like; however, generally, the component (S) is used such that the solid content concentration of the undercoat agent is in a range of 0.1% to 20% by mass, and preferably in a range of 0.2% to 15% by mass.

### (Contact Angle of Water on Surface of Undercoat Agent Layer Formed on Substrate)

With regard to the undercoat agent of the present embodiment, the contact angle of water on the surface of an undercoat agent layer formed by forming a film of the undercoat agent on a substrate and baking the film at 160° C. (hereinafter, also referred to as “contact angle (160° C)”), is preferably 80° or greater, and more preferably 85° or greater.

With regard to the undercoat agent of the present embodiment, the contact angle of water on the surface of an undercoat agent layer formed by forming a film of the undercoat agent on a substrate and baking the film at 240° C. (hereinafter, also referred to as “contact angle (240° C)”), is preferably 80° or greater, more preferably 85° or greater, and even more preferably 88° or greater.

With regard to the undercoat agent of the present embodiment, the difference between the contact angle (240° C.) and the contact angle (160° C.) (contact angle (240° C.)−contact angle (160° C.)) is preferably 5.0° or less, more preferably 3.0° or less, even more preferably 2.0° or less, and particularly preferably 1.5° or less.

When the value of the contact angle is in the above-described preferred range, it is considered that the adhesiveness between the substrate and the layer including a block copolymer, with the undercoat agent layer interposed therebetween, is enhanced. As a result, it is considered that the phase separation performance of the layer including a block copolymer formed on the undercoat agent layer is enhanced. In addition, when the contact angle (160° C.) is within the above-described preferred range, it is considered that sufficient phase separation performance is obtained even when the undercoat agent layer is baked at a temperature of 200° C. or lower (for example, 160° C. to 200° C.).

The above-described contact angles of water are measured, for example, by the following procedure.

Procedure (1): A PGMEA solution of the component (A1) is applied on a substrate and baked at 160° C. or 240° C. for 120 seconds to form an undercoat agent layer having a film thickness of 25 nm. Procedure (2): 2 μL of water is dropped on the surface of the undercoat agent layer, and a contact angle (static contact angle) is measured with a contact angle meter.

The undercoat agent of the present embodiment described above contains a resin component (A1), and the resin component (A1) contains a constitutional unit (u1) and a constitutional unit (u2).

Since the undercoat agent of the present embodiment has a large margin of the baking temperature at the time of forming the undercoat agent layer, the surface state of the undercoat agent layer is likely to be stably controlled. Therefore, the close adhesiveness between the substrate and the layer including a block copolymer formed on the substrate is enhanced through the undercoat agent layer. As a result, it is considered that the phase separation performance of the block copolymer is improved. Since the undercoat agent of the present embodiment has the constitutional unit (u2), and the constitutional unit (u2) includes a primary hydroxy group linked to a linking group having 5 or more carbon atoms, even when the undercoat agent layer is baked at a low temperature (about 160° C. to 200° C.), the close adhesiveness to the substrate is enhanced, and at the same time, the hydrophobicity of the entire undercoat agent layer is increased. Therefore, it is considered that even when the undercoat agent layer is formed by baking at a low temperature, the phase separation performance is maintained.

### <Method for Producing Structure Including Phase-separated Structure>

A second aspect of the present invention is a method for producing a structure including a phase-separated structure. The production method according to the present aspect includes: a step of applying the above-mentioned undercoat agent of the first aspect on a substrate and forming an undercoat agent layer (hereinafter, referred to as “step (i)”); a step of forming a layer including a block copolymer on the undercoat agent layer (hereinafter, referred to as “step (ii)”); and a step of subjecting the layer including the block copolymer to phase separation (hereinafter, referred to as “step (iii)”).

Hereinafter, the method for producing a structure including a phase-separated structure will be specifically described with reference to FIG. 1. However, the present invention is not limited thereto.

FIG. 1 shows an embodiment of the method for producing a structure including a phase-separated structure.

First, the above-mentioned undercoat agent of the first embodiment is applied on a substrate 1 to form an undercoat agent layer 2 (FIG. 1-(I); step (i)).

Next, a composition containing a block copolymer (hereinafter, also referred to as a “BCP composition”) is applied on the undercoat agent layer 2 to form a layer 3 including the block copolymer (FIG. 1-(II); step (ii)).

Next, an annealing treatment is performed by heating, and the layer 3 including the block copolymer is subjected to phase separation into a phase 3a and a phase 3b (FIG. 1-(III); step (iii)).

According to the above-mentioned production method of the present embodiment, that is, the production method including step (i) to step (iii), a structure 3′ including a phase-separated structure is produced on the substrate 1 on which the undercoat agent layer 2 has been formed.

[Step (i)]

In the step (i), the undercoat agent of the first aspect is applied on a substrate 1 to form an undercoat agent layer 2.

By providing the undercoat agent layer 2 on the substrate 1, the hydrophilic-hydrophobic balance between the surface of the substrate 1 and the layer 3 including a block copolymer can be promoted.

That is, since the resin component (A1) contained in the undercoat agent used for the undercoat agent layer 2 has a constitutional unit (u1) and a constitutional unit (u2), the close adhesiveness between the phase formed of a hydrophobic polymer block (b11) in the layer 3 including a block copolymer and the substrate 1 is enhanced.

As a result, it is considered that cylinder structures oriented in the horizontal direction with respect to the surface of the substrate 1 are likely to be formed due to the phase separation of the layer 3 including the block copolymer.

The type of the substrate 1 is not particularly limited as long as the BCP composition can be applied on the surface of the substrate 1. Exemplary examples thereof include a substrate formed from an inorganic material such as a metal (silicon, copper, chromium, iron, aluminum, or the like), glass, titanium oxide, silica, or mica; a substrate formed from a nitride such as SiN; a substrate formed from an oxynitride such as SiON; and a substrate formed from an organic material such as acryl, polystyrene, cellulose, cellulose acetate, or a phenol resin.

The size and shape of the substrate 1 are not particularly limited. The substrate 1 does not necessarily need to have a smooth surface, and substrates of various shapes can be appropriately selected. Exemplary examples include a substrate having a curved surface, a flat plate having a surface with an uneven shape, and a substrate with a flaky shape or the like.

An inorganic and/or organic film may be provided on the surface of the substrate 1.

Examples of the inorganic film include an inorganic antireflection film (inorganic BARC). Examples of the organic film include an organic antireflection film (organic BARC).

The inorganic film can be formed by, for example, applying an inorganic antireflection film composition such as a silicon-based material on a substrate and subjecting the composition to sintering or the like.

For example, the organic film can be formed by applying a material for forming an organic film, in which a resin component and the like constituting the film are dissolved in an organic solvent, on a substrate using a spinner or the like, and baking the film under heating conditions preferably at 200° C. to 300° C., preferably for 30 to 300 seconds, and more preferably for 60 to 180 seconds. This material for forming an organic film does not necessarily need to have sensitivity to light or electron beams, which is essential for a resist film, and may have sensitivity or does not have to have sensitivity. Specifically, a resist or a resin generally used for the production of semiconductor elements or liquid crystal display elements can be used.

In addition, it is preferable that the material for forming an organic film is a material capable of forming an organic film which can be subjected to etching, particularly dry etching, so that the organic film can be etched by using a pattern formed from a block copolymer, which is formed by processing the layer 3, to transfer the pattern onto the organic film, and an organic film pattern can be formed. Above all, the material for forming an organic film is preferably a material capable of forming an organic film capable of being subjected to etching such as oxygen plasma etching. Such a material for forming an organic film may be a material conventionally used for forming an organic film such as organic BARC. Exemplary examples include ARC series manufactured by Nissan Chemical Industries, Ltd., AR series manufactured by Rohm and Haas Company, and SWK series manufactured by Tokyo Ohka Kogyo Co., Ltd.

The method for applying the undercoat agent of the first aspect on a substrate 1 to form an undercoat agent layer 2 is not particularly limited, and the undercoat agent layer 2 can be formed by a conventionally known method.

For example, the undercoat agent layer 2 can be formed by applying the undercoat agent on the substrate 1 by a conventionally known method such as spin coating or using a spinner to form a coating film, and drying the coating film.

The method for drying the coating film may be any method capable of volatilizing the solvent included in the undercoat agent, and exemplary examples include a method of baking (heat treatment). In this case, the baking temperature (heating temperature) is preferably 200° C. or lower. The undercoat agent of the first aspect is such that even when the undercoat agent layer 2 is formed by heat-treating the undercoat agent at a temperature of 200° C. or lower, sufficient phase separation performance of the BCP composition is obtained. The baking temperature is preferably 150° C. to 200° C., more preferably 160° C. to 190° C., even more preferably 160° C. to 180° C., and particularly preferably 160° C. to 170° C. The baking time is preferably 30 to 500 seconds, more preferably 60 to 400 seconds, even more preferably 100 to 300 seconds, and still more preferably 100 to 200 seconds.

The baking time and the baking temperature can be optionally combined.

The thickness of the undercoat agent layer 2 after drying of the coating film is preferably about 10 to 100 nm, more preferably about 20 to 90 nm, and even more preferably about 20 to 50 nm.

The surface of the substrate 1 may be cleaned in advance before forming the undercoat agent layer 2 on the substrate 1. By cleaning the surface of the substrate 1, the coatability of the undercoat agent is improved.

Regarding the cleaning treatment method, conventionally known methods can be utilized, and examples thereof include an oxygen plasma treatment, an ozone oxidation treatment, an acid alkali treatment, and a chemical modification treatment.

After the undercoat agent layer 2 is formed, the undercoat agent layer 2 may be rinsed as necessary, by using a rinse liquid such as a solvent. Since uncrosslinked portions and the like in the undercoat agent layer 2 are removed by this rinsing, the affinity with at least one polymer (block) constituting the block copolymer is improved, and a phase-separated structure composed of cylinder structures oriented in a direction perpendicular to the surface of the substrate 1 is likely to be formed.

The rinse liquid may be any one that can dissolve uncrosslinked portions, and a solvent such as propylene glycol monomethyl ether acetate (PGMEA), propylene glycol monomethyl ether (PGME), or ethyl lactate (EL), or a commercially available thinner liquid can be used.

In addition, after the cleaning, post-baking may be performed in order to volatilize the rinse liquid. The temperature conditions for this post-baking are preferably 80° C. to 300° C., more preferably 100° C. to 250° C., even more preferably 100° C. to 200° C., and particularly preferably 100° C. to 150° C. The baking time is preferably 30 to 500 seconds, and more preferably 60 to 240 seconds. The thickness of the undercoat agent layer 2 after such post-baking is preferably about 1 to 10 nm, and more preferably about 2 to 7 nm.

[Step (ii)]

In step (ii), a layer 3 including a block copolymer in which a plurality of kinds of blocks are bonded is formed on the undercoat agent layer 2. As the block copolymer, a block copolymer in which the hydrophobic polymer block (b11) and the hydrophilic polymer block (b21) as mentioned above are bonded, can be employed. The method for forming the layer 3 on the undercoat agent layer 2 is not particularly limited, and an exemplary example thereof is a method of applying a BCP composition on the undercoat agent layer 2 by a conventionally known method such as spin coating or using a spinner to form a coating film, and drying the coating film. The details of such a BCP composition will be described later.

The thickness of the layer 3 may be a thickness sufficient to induce phase separation, and when considering the type of the substrate 1, or the structure period size, the uniformity of the nanostructures, or the like of the phase-separated structure to be formed, the thickness is preferably 20 to 100 nm, and more preferably 30 to 80 nm.

For example, when the substrate 1 is a Cu substrate, the thickness of the layer 3 is preferably 10 to 100 nm, and more preferably 30 to 80 nm.

[Step (iii)]

In step (iii), the layer 3 including the block copolymer is subjected to phase separation.

When the substrate 1 after the step (ii) is heated to perform an annealing treatment, a phase-separated structure is formed such that at least a portion of the surface of the substrate 1 is exposed by selective removal of the block copolymer. That is, a structure 3′ including a phase-separated structure that is phase-separated into a phase 3a and a phase 3b is produced on the substrate 1.

Regarding the temperature conditions for the annealing treatment, it is preferable that the annealing treatment is performed at a temperature equal to or higher than the glass transition temperature of the block copolymer used and lower than the thermal decomposition temperature. For example, when the block copolymer is a polystyrene-polymethyl methacrylate (PS-PMMA) block copolymer (weight-average molecular weight: 5,000 to 100,000), the temperature is preferably 180° C. to 270° C. The heating time is preferably 30 to 3,600 seconds.

In addition, it is preferable that the annealing treatment is performed in a gas having low reactivity, such as nitrogen.

According to the method for producing a structure including a phase-separated structure of the present embodiment as described above, since an undercoat agent layer is formed by using the above-mentioned undercoat agent of the first aspect, the phase separation performance of the block copolymer can be enhanced, and fine structures having a favorable shape can be formed. Moreover, since the baking temperature for the undercoat agent layer can be lowered as compared with conventional undercoat agents, further increase in the efficiency of the process and energy saving can be promoted.

### [Optional Steps]

The method for producing a structure including a phase-separated structure of the present embodiment is not limited to the above-described embodiments and may have steps (optional steps) other than the steps (i) to (iii).

Examples of such optional steps include a step of selectively removing a phase formed of at least one kind of block among the plurality of kinds of blocks constituting the block copolymer from the layer including the block copolymer (hereinafter, referred to as “step (iv)”, and a guide pattern forming step.
As to Step (iv)

In step (iv), a phase formed of at least one kind of block among the plurality of kinds of blocks constituting the block copolymer is selectively removed from the layer including the block copolymer, which is formed on the undercoat agent layer. As a result, a fine pattern (polymer nanostructures) is formed.

Examples of the method for selectively removing a phase formed of blocks include a method for performing an oxygen plasma treatment on the layer including the block copolymer, and a method for performing a hydrogen plasma treatment.

In the following description, among the blocks constituting the block copolymer, a block that is not selectively removed is referred to as a P_{A} block, and a block that is selectively removed is referred to as a P_{B} block. For example, after the layer including the PS-PMMA block copolymer is subjected to phase separation, a phase formed of PMMA is selectively removed by performing an oxygen plasma treatment, a hydrogen plasma treatment, or the like on the layer. In this case, the PS portion is the P_{A} block, and the PMMA portion is the P_{B} block.

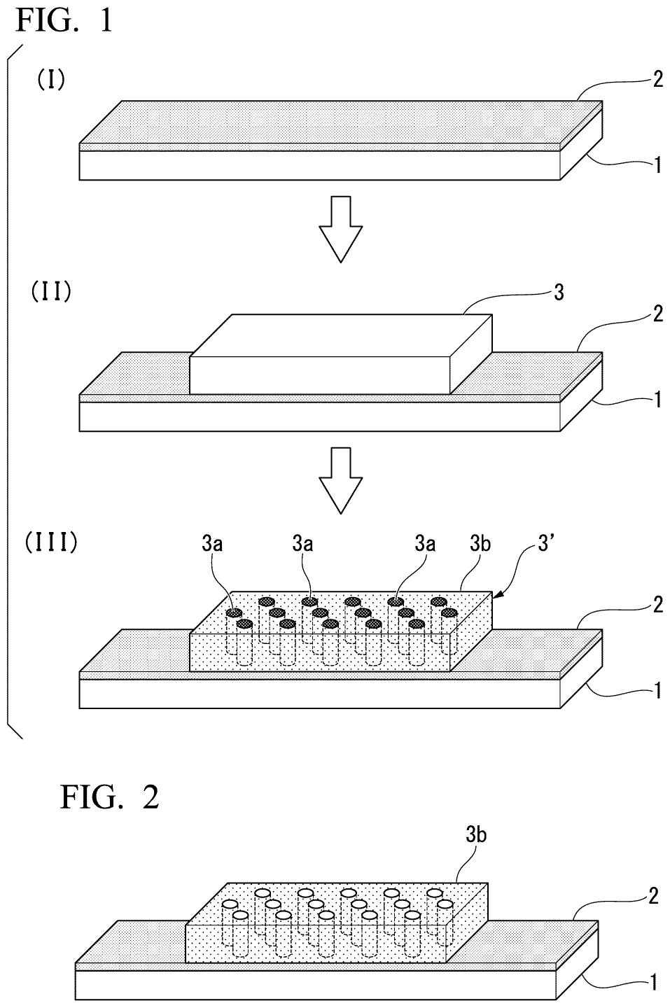

FIG. 2 shows an exemplary embodiment of step (iv).

In the embodiment shown in FIG. 2, when the structure 3′ produced on the substrate 1 is subjected to an oxygen plasma treatment in step (iii), the phase 3a is selectively removed, and a pattern (polymer nanostructures) composed of the separated phase 3b is formed. In this case, the phase 3b is a phase formed of the P_{A} block, and the phase 3a is a phase formed of the P_{B} block.

The substrate 1 having a pattern formed thereon by phase separation of the layer 3 formed from the block copolymer as described above, can be used as it is; however, the shape of the pattern (polymer nanostructures) on the substrate 1 may be changed by further heating the substrate 1.

Regarding the temperature conditions for heating, a temperature equal to or higher than the glass transition temperature of the block copolymer to be used and lower than the thermal decomposition temperature is preferred. In addition, heating is preferably performed in a gas having low reactivity, such as nitrogen.
As to Guide Pattern Forming Step

The method for producing a structure including a phase-separated structure according to the present invention may have a step of providing a guide pattern on the undercoat agent layer (guide pattern forming step) between the step (i) and the step (ii). As a result, it is possible to control the array structure of the phase-separated structures.

For example, in a case where a guide pattern is not provided, even for a block copolymer with which a random fingerprint-shaped phase-separated structure is formed, when a groove structure of a resist film is provided on the surface of the undercoat agent layer, a phase-separated structure oriented along the grooves is obtained. According to such a principle, a guide pattern may be provided on the undercoat agent layer 2. In addition, when the surface of the guide pattern has an affinity with any of the polymers constituting the block copolymer, a phase-separated structure composed of cylinder structures oriented in a direction perpendicular to the surface of the substrate is likely to be formed.

The guide pattern can be formed by using, for example, a resist composition.

As the resist composition for forming the guide pattern, among the resist compositions and modified products thereof that are generally used for the formation of resist patterns, any one having an affinity with any of the polymers constituting the block copolymer can be appropriately selected and used. The resist composition may be any of a positive-type resist composition for forming a positive-type pattern in which the exposed part of the resist film is dissolved and removed, and a negative-type resist composition for forming a negative-type pattern in which the unexposed part of the resist film is dissolved and removed; however, and the resist composition is preferably a negative-type resist composition. As the negative-type resist composition, for example, a resist composition containing an acid generator, and a base material component whose solubility in a liquid developer containing an organic solvent is decreased by the action of an acid, and in which the base material component contains a resin component having a constitutional unit which is decomposed by the action of an acid to have increased polarity, is preferable.

After the BCP composition is poured on the undercoat agent layer on which the guide pattern has been formed, an annealing treatment is performed to induce phase separation. Therefore, the resist composition for forming the guide pattern is preferably a composition capable of forming a resist film having excellent solvent resistance and heat resistance.
As to Composition Containing Block Copolymer (BCP Composition)

The BCP composition can be prepared by dissolving the above-mentioned block copolymer in an organic solvent. Examples of this organic solvent include those solvents similar to the component (S) described above as the organic solvent that can be used for the undercoat agent.

The organic solvent included in the BCP composition is not particularly limited, the content is appropriately set at a concentration at which the BCP composition can be applied, according to the coating film thickness, and the organic solvent is used such that the solid content concentration of the block copolymer is generally in the range of 0.2% to 70% by mass, and preferably in the range of 0.2% to 50% by mass.

The BCP composition can further contain miscible additives as appropriate and as desired, for example, an additive resin for ameliorating the performance of the undercoat agent layer, a surfactant for improving coatability, a dissolution inhibitor, a plasticizer, a stabilizer, a colorant, a halation preventing agent, a dye, a sensitizer, a base multiplier, and a basic compound, in addition to the above-described block copolymer and the organic solvent.

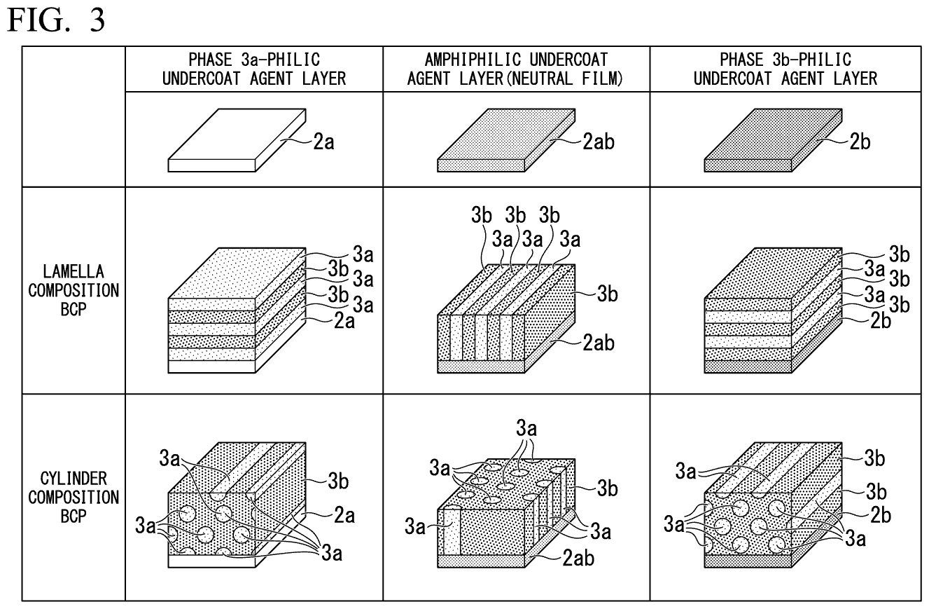

FIG. 3 is a diagram schematically showing an example of the structure including a phase-separated structure, which is produced by the production method of the present embodiment. In FIG. 3, the “lamella composition BCP” indicates a case in which a block copolymer that forms a lamella phase-separated structure is used. The “cylinder composition BCP” indicates a case in which a block copolymer that forms a cylinder phase-separated structure is used. By adjusting the composition (molecular weight, molar ratio, and the like of each block) of the block copolymer, a lamella composition BCP or a cylinder composition BCP can be obtained.

For example, when the undercoat agent of the first aspect has an affinity for the polymer block constituting the phase 3a, a phase 3a-philic undercoat agent layer 2a is formed by the step (i) (upper row in the left column of FIG. 3). Next, when a phase-separated structure is formed by the step (ii) and the step (iii), a lamella structure (middle row in the left column of FIG. 3) or a cylinder structure (lower row in the left column of FIG. 3) can be formed depending on the composition of the block copolymer. In the lamella structure, a horizontal lamella structure is formed, in which the phase 3a is present in contact with the phase 3a-philic undercoat agent layer 2a. In the cylinder structure, a horizontal cylinder structure is formed, in which the cylinders of the phase 3a are present in contact with the phase 3a-philic undercoat agent layer 2a.

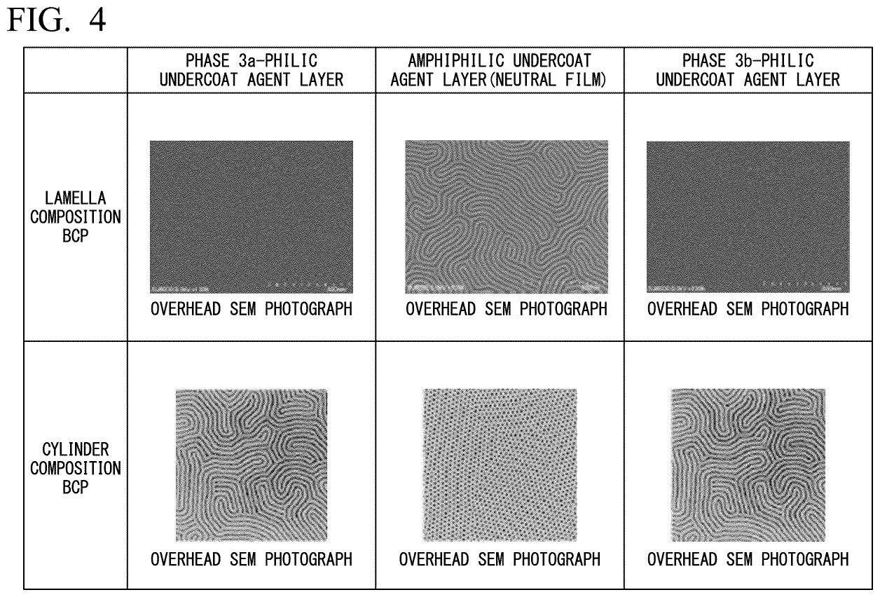

The upper row in the left column of FIG. 4 shows an example of an overhead SEM photograph of a horizontal lamella phase-separated structure formed by using the phase 3a-philic undercoat agent layer 2a. Since the horizontal lamella has a structure in which the phase 3a and the phase 3b are repeatedly laminated horizontally, no pattern is observed in the overhead SEM photograph.

The lower row in the left column of FIG. 4 shows an example of an overhead SEM photograph of a horizontal cylinder phase-separated structure formed by using the phase 3a-philic undercoat agent layer 2a. Since no guide pattern is used, the horizontal cylinder has an undulated shape (horizontal cylinder).

For example, when the undercoat agent of the first aspect has an affinity for the polymer block constituting the phase 3b, a phase 3b-philic undercoat agent layer 2b is formed by the step (i) (upper row in the right column of FIG. 3). Next, when a phase-separated structure is formed by the step (ii) and the step (iii), a lamella structure (middle row in the right column of FIG. 3) or a cylinder structure (lower row in the right column of FIG. 3) can be formed depending on the composition of the block copolymer. In the lamella structure, a horizontal lamella structure is formed, in which the phase 3b is present in contact with the phase 3b-philic undercoat agent layer 2b. In the cylinder structure, a horizontal cylinder structure is formed, in which the cylinders of the phase 3a are present without being in contact with the phase 3b-philic undercoat agent layer 2a.

The upper row in the right column of FIG. 4 shows an example of an overhead SEM photograph of a horizontal lamella phase-separated structure formed by using the phase 3b-philic undercoat agent layer 2b. Since the horizontal lamella has a structure in which the phase 3b and the phase 3a are repeatedly laminated horizontally, no pattern is observed in the overhead SEM photograph.

The lower row in the right column of FIG. 4 shows an example of an overhead SEM photograph of a horizontal cylinder phase-separated structure formed by using the phase 3b-philic undercoat agent layer 2b. Since no guide pattern is used, a horizontal cylinder structure is formed.

For example, when the undercoat agent of the first aspect has an affinity for both the polymer blocks of the phase 3a and the phase 3b, an amphiphilic undercoat agent layer 2ab is formed by the step (i) (upper row in the middle column). Next, when a phase-separated structure is formed by the step (ii) and the step (iii), a lamella structure (middle row in the middle column) or a cylinder structure (lower row in the middle column) can be formed depending on the composition of the block copolymer. The lamella structure is a vertical lamella structure in which repeating structures of the phase 3a and the phase 3b are formed perpendicularly to the amphiphilic undercoat agent layer 2ab. The cylinder structure is a vertical cylinder structure in which cylinders of the phase 3a are formed perpendicularly to the amphiphilic undercoat agent layer 2ab.

The upper row in the middle column of FIG. 4 shows an example of an overhead SEM photograph of a vertical lamella phase-separated structure formed by using the amphiphilic undercoat agent layer 2ab. Vertical lamellae (fingerprints) in an undulated state are observed.

The lower row in the middle column of FIG. 4 shows an example of an overhead SEM photograph of a vertical cylinder phase-separated structure formed by using the amphiphilic undercoat agent layer 2ab. Since no guide pattern is used, the vertical cylinders are in a state of being randomly disposed (vertical cylinders).

Examples of the polymer block constituting the phase 3a include a hydrophobic polymer block (b11). Examples of the polymer block constituting the phase 3b include a hydrophilic polymer block (b21).

The hydrophobic polymer block (b11) is not particularly limited as long as it has a relatively low affinity for water with respect to the hydrophilic polymer block (b21); however, exemplary examples include a block in which a constitutional unit derived from styrene or a styrene derivative is repeatedly bonded.

The hydrophilic polymer block (b21) is not particularly limited as long as it has a relatively high affinity for water with respect to the hydrophobic polymer block (b11); however, exemplary examples include a block in which a constitutional unit derived from an (α-substituted) acrylic acid ester is repeatedly bonded, and a block in which a constitutional unit derived from an (α-substituted) acrylic acid is repeatedly bonded.

The production method of the present embodiment can be suitably used for the production of a structure including a phase-separated structure having a horizontal lamella structure or a horizontal cylinder structure. The undercoat agent of the first aspect tends to have a high affinity with the hydrophobic polymer block (b11). Therefore, the undercoat agent is suitable for the production of a structure including the horizontal lamella phase-separated structure shown in the middle row in the left column of FIG. 3 or the horizontal cylinder phase-separated structure shown in the lower row in the left column of FIG. 3.

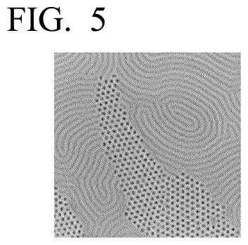

Depending on the undercoat agent layer, the phase separation of the block copolymer cannot be sufficiently controlled, and a phase-separated structure in which a horizontal structure and a vertical structure are present in a mixed state may be formed. For example, the overhead SEM photograph of FIG. 5 shows an example of a phase-separated structure in which horizontal cylinders and vertical cylinders are present in a mixed state.

In the production method of the present embodiment, since the undercoat agent of the first aspect is used, phase separation can be sufficiently controlled. For this reason, mixed presence of the horizontal structure and the vertical structure is suppressed. For example, a structure including a phase-separated structure of horizontal lamellae, in which mixed presence of vertical lamellae is suppressed, can be obtained by the production method of the present embodiment. Alternatively, a structure including a phase-separated structure of horizontal cylinders, in which mixed presence of vertical cylinders is suppressed, can be obtained by the production method of the present embodiment.

### EXAMPLES

Hereinafter, the present invention will be described in more detail by way of Examples; however, the present invention is not limited to these examples.

### Synthesis Example of High-molecular Weight Compound

### (Synthesis of High-molecular Weight Compound (A1-1))

21.60 g of propylene glycol monomethyl ether acetate (PGMEA) was introduced into a three-necked flask to which a thermometer, a reflux tube, and a nitrogen inlet tube were connected, and was heated to 80° C. 40.00 g (384.06 mmol) of compound (m1-1) and 0.72 g (3.88 mmol) of compound (m2-1) were dissolved in 61.08 g of PGMEA, and 2.68 g (11.64 mmol) of dimethyl azobisisobutyrate (V-601) as a polymerization initiator was added to the solution and dissolved therein to prepare solution (1). The solution (1) was added dropwise to the PGMEA heated to 80° C. as described above, for 4 hours in a nitrogen atmosphere. After completion of the dropwise addition, the reaction solution was heated and stirred for 2 hours, and then the reaction solution was cooled to room temperature.

The obtained reaction polymerization liquid was added dropwise to a large amount of methanol to perform an operation of precipitating a polymer. A precipitated white powder was washed with a large amount of methanol and dried to obtain 23.13 g (yield: 56.8%) of a target high-molecular weight compound (A1-1).

The weight-average molecular weight (Mw) in terms of the standard polystyrene equivalent value, which was determined by GPC measurement of the high-molecular weight compound (A1-1), was 9,300, and the molecular weight dispersity (Mw/Mn) was 1.58. The copolymerization composition ratio (proportion (molar ratio) of each constitutional unit in the structural formula) determined from the carbon 13 nuclear magnetic resonance spectrum (600 MHz_¹³C-NMR) of the high-molecular weight compound (A1-1) was l/m=98.9/1.1.

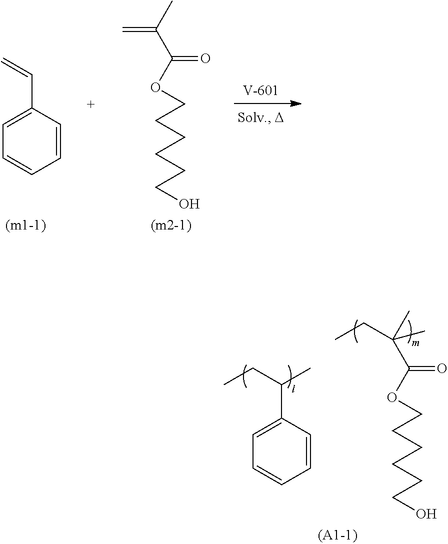

### (Synthesis of High-molecular Weight Compounds (A1-2) to (A1-11))

High-molecular weight compounds (A1-2) to (A1-11) were synthesized in the same manner as in the case of the high-molecular weight compound (A1-1), by using any of the compounds (m1-1) to (m1-3) and any of the compounds (m2-1) to (m2-6).

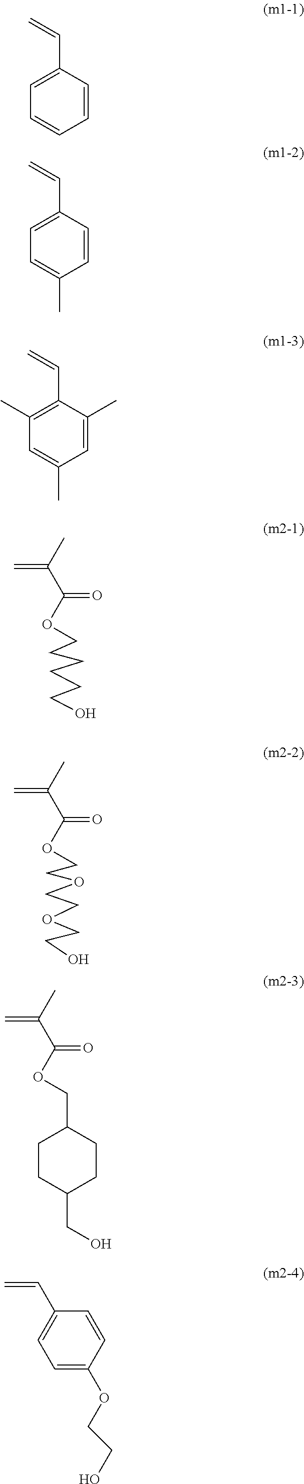

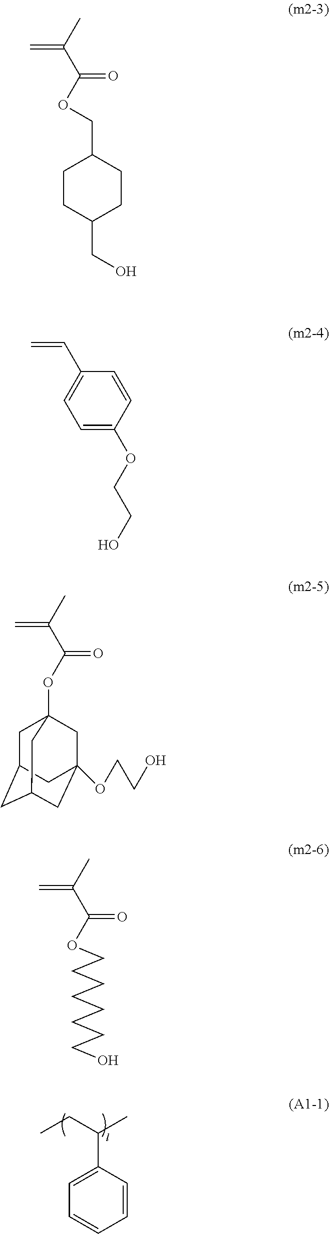

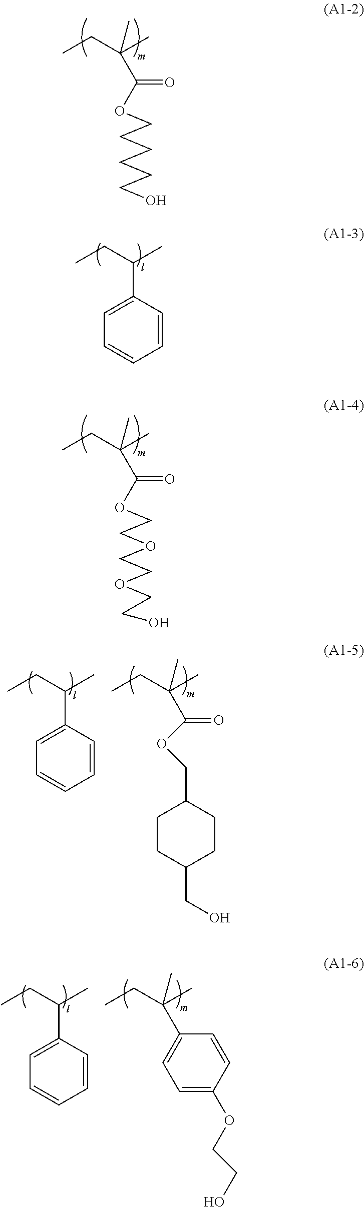

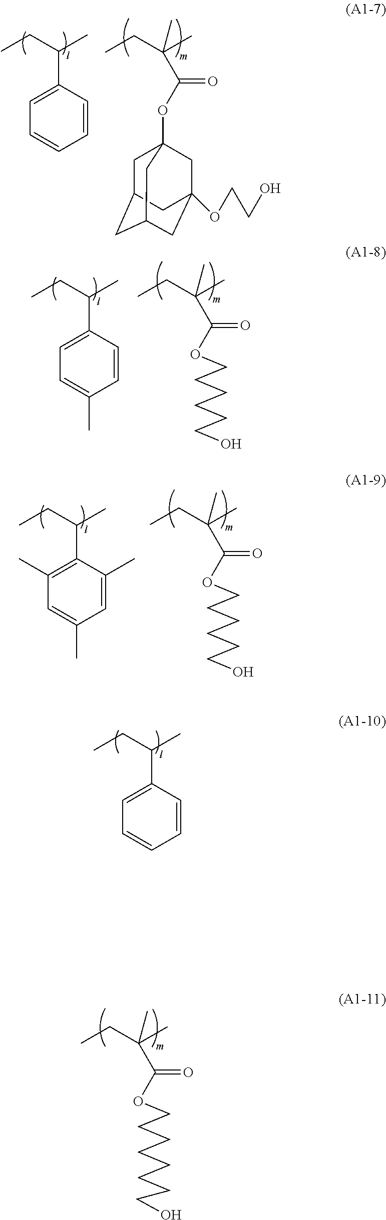

For each of the high-molecular weight compounds (A1-1) to (A1-11), the copolymerization composition ratio (proportion (molar ratio) of each constitutional unit in the structural formula) determined from the carbon 13 nuclear magnetic resonance spectrum (600 MHz_¹³C-NMR), and the standard polystyrene-equivalent weight-average molecular weight (Mw) and the molecular weight dispersity (Mw/Mn) determined by GPC measurement are shown in Table 1.

TABLE 1

| | | | Copolymerization | | | |
|---|---|---|---|---|---|---|
| | | | composition ratio | | | |
| | Monomer | | l | m | Mw | Mw/Mn |
| A1-1 | m1-1 | m2-1 | 98.9 | 1.1 | 9300 | 1.58 |
| A1-2 | m1-1 | m2-1 | 99.0 | 1.0 | 19400 | 1.88 |
| A1-3 | m1-1 | m2-1 | 97.1 | 2.9 | 9400 | 1.60 |
| A1-4 | m1-1 | m2-2 | 98.8 | 1.2 | 10100 | 1.59 |
| A1-5 | m1-1 | m2-3 | 98.7 | 1.3 | 10500 | 1.61 |
| A1-6 | m1-1 | m2-4 | 98.9 | 1.1 | 10300 | 1.60 |
| A1-7 | m1-1 | m2-5 | 98.1 | 1.9 | 10900 | 1.62 |
| A1-8 | m1-2 | m2-1 | 98.0 | 2.0 | 8700 | 1.58 |
| A1-9 | m1-3 | m2-1 | 98.5 | 1.5 | 9100 | 1.59 |
| A1-10 | m1-1 | m2-6 | 98.8 | 1.2 | 9800 | 1.61 |
| A1-11 | m1-1 | m2-6 | 96.8 | 3.2 | 10800 | 1.63 |

The compound (m2-6) used for the synthesis of the high-molecular weight compounds (A1-10) and (A1-11) was synthesized as follows.

5.00 g (34.19 mmol) of 1,8-octanediol and 45.00 g of dichloromethane (CH₂Cl₂) were introduced into a 300-mL three-necked flask to which a stirrer, a thermometer, a dropping funnel, and a nitrogen inlet tube were connected, and the mixture was completely dissolved at room temperature. Next, 5.19 g (51.29 mmol) of triethylamine (TEA) and 0.42 g (3.42 mmol) of dimethylaminopyridine (DMAP) were introduced into a three-necked flask, and the mixture was completely dissolved at room temperature and then kept in an ice bath at 5° C. or lower.

A mixed solution of 32.13 g of dichloromethane and 3.57 g (34.19 mmol) of methacryloyl chloride was transferred into a dropping funnel and was added dropwise for 1 hour or longer such that the temperature inside the flask reached 10° C. or lower. After the dropwise addition, the reaction solution was stirred at 5° C. or lower for 1 hour and stirred at room temperature for 3 hours (the reaction was monitored by HPLC). After the reaction, the reaction solution was subjected to an ice bath at 5° C. or lower, and 100 g of pure water was added thereto.

The reaction solution was transferred into a separatory funnel, the organic phase was extracted, and subsequently, the organic phase was washed twice with 5% aqueous ammonia, twice with 1% aqueous hydrochloric acid, and twice with pure water. The organic phase was concentrated in an evaporator, and 6.23 g (yield: 85%, HPLC purity (210 nm): 98.8%) of the compound (m2-6) was obtained. The obtained compound (m2-6) was subjected to distillation (HPLC purity (210 nm): 99.4%) and was used for the polymerization (radical polymerization) for synthesizing the high-molecular weight compound (A1-10) or (A1-11).

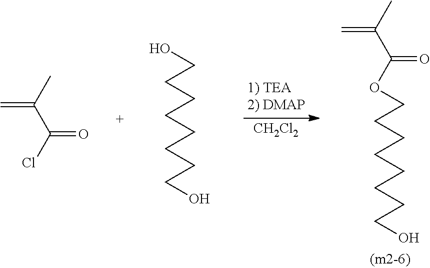

### <Preparation of Undercoat Agent>

Each component shown in Table 2 was mixed and dissolved, and an undercoat agent (solid content concentration of 1.0% by mass) of each example was prepared.

TABLE 2

| | Component (A) | Component (S) |
|---|---|---|
| Example 1 | (A1)-1 | (S)-1 |
| | [100] | [9900] |
| Example 2 | (A1)-2 | (S)-1 |
| | [100] | [9900] |
| Example 3 | (A1)-3 | (S)-1 |
| | [100] | [9900] |
| Example 4 | (A1)-4 | (S)-1 |
| | [100] | [9900] |
| Example 5 | (A1)-5 | (S)-1 |
| | [100] | [9900] |
| Example 6 | (A1)-6 | (S)-1 |
| | [100] | [9900] |
| Example 7 | (A1)-7 | (S)-1 |
| | [100] | [9900] |
| Example 8 | (A1)-8 | (S)-1 |
| | [100] | [9900] |
| Example 9 | (A1)-9 | (S)-1 |
| | [100] | [9900] |
| Example 10 | (A1)-10 | (S)-1 |
| | [100] | [9900] |
| Example 11 | (A1)-11 | (S)-1 |
| | [100] | [9900] |
| Comparative | (A2)-1 | (S)-1 |
| Example 1 | [100] | [9900] |
| Comparative | (A2)-2 | (S)-1 |
| Example 2 | [100] | [9900] |
| Comparative | (A2)-3 | (S)-1 |
| Example 3 | [100] | [9900] |

In Table 2, each abbreviation has the following meaning. The numerical values in the brackets represent blending amounts (parts by mass).

(A1)-1 to (A1)-11: High-molecular weight compounds (A1-1) to (A1-11) described above.

(A2)-1: The following high-molecular weight compound (A2-1). The weight-average molecular weight (Mw) is 10,300, the molecular weight dispersity (Mw/Mn) is 1.61, and the copolymerization composition ratio (proportion (molar ratio) of each constitutional unit in the structural formula) is l/m =98.9/1.1. (A2)-2: The following high-molecular weight compound (A2-2). The weight-average molecular weight (Mw) is 10,200, the molecular weight dispersity (Mw/Mn) is 1.60, and the copolymerization composition ratio (proportion (molar ratio) of each constitutional unit in the structural formula) is l/m =98.8/1.2.

(A2)-3: The following high-molecular weight compound (A2-3). The weight-average molecular weight (Mw) is 9,900, the molecular weight dispersity (Mw/Mn) is 1.61, and the copolymerization composition ratio (proportion (molar ratio) of each constitutional unit in the structural formula) is l/m=98.8/1.2.

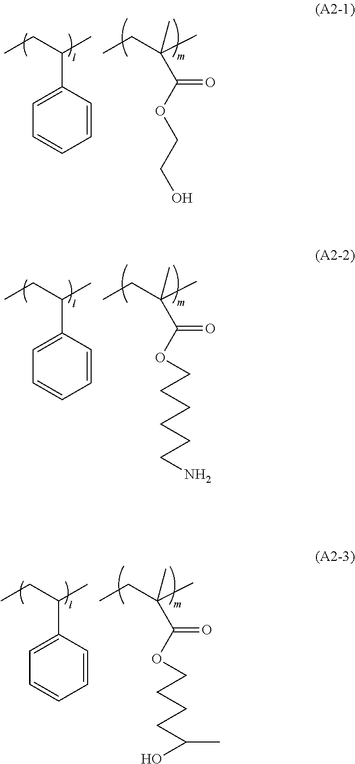

(S)-1: Propylene glycol monomethyl ether acetate (PGMEA)

The compound (m3) used for the synthesis of the high-molecular weight compound (A2-3) was synthesized as follows.

5.00 g (42.31 mmol) of 1,5-hexanediol and 45.00 g of dichloromethane (CH₂Cl₂) were introduced into a 300-mL three-necked flask to which a stirrer, a thermometer, a dropping funnel, and a nitrogen inlet tube were connected, and the mixture was stirred at room temperature. Next, 6.24 g (63.46 mmol) of triethylamine (TEA) and 0.52 g (4.23 mmol) of dimethylaminopyridine (DMAP) were introduced into a three-necked flask, and the mixture was completely dissolved at room temperature and then kept in an ice bath at 5° C. or lower.

A mixed solution of 39.80 g of dichloromethane and 4.42 g (42.31 mmol) of methacryloyl chloride was transferred into a dropping funnel and was added dropwise for 1 hour or longer such that the temperature inside the flask reached 10° C. or lower. After the dropwise addition, the reaction solution was stirred at 5° C. or lower for 1 hour and stirred at room temperature for 3 hours (the reaction was monitored by HPLC). After the reaction, the reaction solution was subjected to an ice bath at 5° C. or lower, and 100 g of pure water was added thereto.

The reaction solution was transferred into a separatory funnel, the organic phase was extracted, and subsequently, the organic phase was washed twice with 5% aqueous ammonia, twice with 1% aqueous hydrochloric acid, and twice with pure water. The organic phase was concentrated in an evaporator, and 6.23 g (yield: 92%, HPLC purity (210 nm): 97.8%) of the compound (m3) was obtained. The obtained compound (m3) was subjected to distillation (HPLC purity (210 nm): 99.6%) and was used for the polymerization (radical polymerization) for synthesizing the high-molecular weight compound (A2-3).

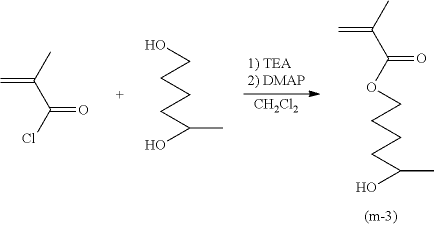

### <Synthesis of Block Copolymer>

0.12 g (2.93 mmol) of lithium chloride (LiCl) and 161 g of tetrahydrofuran (THF) were introduced into a Schlenk tube in an argon atmosphere, and the mixture was cooled to −78° C. After the inside of the Schlenk tube was dewatered and degassed, 0.27 ml of Sec-butyllithium (1.07 mol/l, hexane-cyclohexane mixed solution, 0.29 mmol) as an anionic polymerization initiator was introduced into the tube in an argon atmosphere, subsequently 22.1 ml (192 mmol) of styrene was introduced therein, and then the mixture was stirred at −78° C. for 30 minutes. After stirring, 0.077 ml (0.44 mmol) of diphenylethylene (DPE) was introduced therein, and stirring was performed at −78° C. for 30 minutes. Furthermore, 9.03 ml (84.80 mmol) of methyl methacrylate was introduced therein, and stirring was performed at −78° C. for 180 minutes. After stirring, 1 ml (25 mmol) of methanol as a polymerization terminator was introduced therein at −78° C. to stop the reaction.

An operation of adding dropwise the obtained reaction polymerization liquid to a large amount of methanol to precipitate a polymer was carried out, a precipitated white powder was washed with a large amount of methanol, washed with a large amount of pure water, and then dried, and 21.8 g (yield: 73.8%) of block copolymer (BCP1) as a target product was obtained.

The standard polystyrene-equivalent number average molecular weight (Mn) of

BCP1 determined by GPC measurement was 98,500, and the molecular weight dispersity (Mw/Mn) was 1.05. The copolymerization composition ratio (proportion (molar ratio) of each constitutional unit in the structural formula) determined from the carbon 13 nuclear magnetic resonance spectrum (600 MHz_¹³C-NMR) of BCP1 was polystyrene (PS)/polymethyl methacrylate (PMMA)=69.8/30.2.

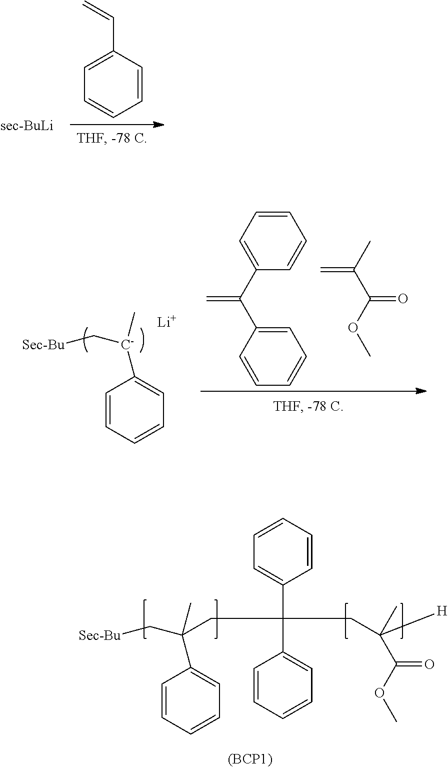

### <Production of Structure Including Phase-separated Structure>

[Step (i)]

The undercoat agent composition of each example was applied on a 12-inch silicon wafer dehydrobaked at 200° C. for 60 seconds by using a spinner (speed of rotation: 1,500 rpm), baked at 160° C. to 240° C. for 120 seconds, and then dried to form an undercoat agent layer having a film thickness of 25 nm. This undercoat agent layer was rinsed with OK73 thinner (trade name, manufactured by Tokyo Ohka Kogyo Co., Ltd.) to remove a random copolymer in uncrosslinked portions and the like. Thereafter, the film was baked at 100° C. for 60 seconds.

### Step (ii):

A PGMEA solution of BCP1 (block copolymer concentration: 1.6% by mass) was applied by spin coating (speed of rotation: 1,500 rpm) so as to cover the undercoat agent layer. Next, the substrate on which the PGMEA solution of BCP1 was applied was baked and dried at 90° C. for 60 seconds to form a layer including the block copolymer with a film thickness of 52 nm.

Step (iii):

The layer including the block copolymer was heated at 260° C. for 15 minutes under a nitrogen gas stream to be annealed, and thereby the layer was subjected to phase separation into a phase formed of PS and a phase formed of PMMA to form a phase-separated structure.

### Step (iv):

The silicon wafer having the phase-separated structure formed thereon was subjected to an oxygen plasma treatment (200 mL/min, 40 Pa, 40° C., 200 W, 10 seconds) by using TCA-3822 (manufactured by Tokyo Ohka Kogyo Co., Ltd.), and the phase formed of PMMA was selectively removed.

### [Evaluation of Phase Separation Performance]

The surface (in a phase-separated state) of the substrate obtained after the step (iv) was observed with a scanning electron microscope SEM (SU8000, manufactured by Hitachi High-Technologies Corporation).

Through such observation, the formation of a horizontal cylinder shape was recognized, and the lowest temperature of the baking temperature for the undercoat agent when the formation of the horizontal cylinder shape was recognized was checked. The results are shown in Table 3 as “Horizontal cylinder forming temperature (° C.)”.

[Measurement of contact angle of water on surface of undercoat agent layer]

An undercoat agent layer was formed by the step (i) by setting the baking temperature for the undercoat agent to 160° C. or 240° C. Water was dropped onto the surface of the undercoat agent layer, and the contact angle (static contact angle) was measured by using a DROP MASTER-700 (product name, manufactured by Kyowa Interface Science Co., Ltd.) (measurement of contact angle: 2 μL of water). The contact angle at the baking temperature of 160° C. for the undercoat agent is indicated in Table 3 as “160° C. contact angle”, and the contact angle at the baking temperature of 240° C. is indicated as “240° C. contact angle”. The difference between the 240° C. contact angle and the 160° C. contact angle (240° C. contact angle−160° C. contact angle) is indicated in Table 3 as “ΔContact angle)(°)”.

TABLE 3

| | 160° C. | 240° C. | | Horizontal |
|---|---|---|---|---|
| | contact | contact | ΔContact | cylinder forming |
| | angle (°) | angle (°) | angle (°) | temperature (° C.) |
| Example 1 | 87.9 | 88.5 | 0.6 | 160 |
| Example 2 | 88.3 | 88.8 | 0.5 | 160 |
| Example 3 | 85.5 | 88.1 | 2.6 | 160 |
| Example 4 | 86.5 | 88.0 | 1.5 | 170 |
| Example 5 | 86.0 | 88.3 | 2.3 | 170 |
| Example 6 | 88.5 | 89.1 | 0.6 | 160 |
| Example 7 | 86.5 | 88.5 | 2.0 | 180 |
| Example 8 | 88.0 | 89.1 | 1.1 | 165 |
| Example 9 | 88.4 | 89.3 | 0.9 | 165 |
| Example 10 | 87.4 | 88.1 | 0.7 | 160 |
| Example 11 | 85.7 | 88.3 | 2.6 | 160 |
| Comparative | 82.2 | 88.5 | 6.3 | 210 |
| Example 1 | | | | |
| Comparative | 45.0 | 72.1 | 27.1 | — |
| Example 2 | | | | |
| Comparative | 68.2 | 81.4 | 13.2 | — |
| Example 3 | | | | |

As shown in Table 3, in the cases of the undercoat agents of Examples 1 to 11, the contact angle at the baking temperature for the undercoat agent of 160° C. was larger, and the difference between the 240° C. contact angle and the 160° C. contact angle was small, as compared with the undercoat agents of Comparative Examples 1 to 3. In addition, when a phase-separated structure was formed by using the undercoat agents of Examples 1 to 11, a horizontal cylinder shape was formed at a lower baking temperature for the undercoat agent as compared with the case where the undercoat agent of Comparative Example 1 was used. In Comparative Examples 2 and 3, the horizontal cylinder shape could not be formed at the baking temperature for the undercoat agent of 160° C. to 240° C.

From the results given above, it was verified that the undercoat agents of Examples 1 to 11 enable the formation of an undercoat agent layer having a higher affinity with a hydrophobic polymer block at a low baking temperature.

While preferred embodiments of the invention have been described and illustrated above, it should be understood that these are exemplary examples of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

### EXPLANATION OF REFERENCES

1 support

2 undercoat agent layer

2a phase 3a-philic undercoat agent layer

2b phase 3b-philic undercoat agent layer

2ab amphiphilic undercoat agent layer

3 BCP layer

3′ structure

3a phase

3b phase

What is claimed is:

1. An undercoat agent used for subjecting a layer including a block copolymer to phase separation on a substrate, the undercoat agent comprising:
a resin component (A1) having a constitutional unit (u1) represented by General Formula (u1) and a constitutional unit (u2) represented by General Formula (u2): 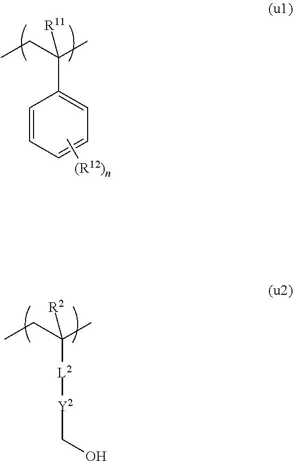
wherein, in General Formula (u1), R¹¹ represents a hydrogen atom, an alkyl group having 1 to 5 carbon atoms, or a halogenated alkyl group having 1 to 5 carbon atoms, R¹² represents a substituent, and n represents an integer of 0 to 5,
in General Formula (u2), R² represents a hydrogen atom, an alkyl group having 1 to 5 carbon atoms, or a halogenated alkyl group having 1 to 5 carbon atoms, L² represents a single bond or a divalent linking group, and Y² represents a divalent linking group having 5 to 15 carbon atoms.

2. A method for producing a structure including a phase-separated structure, the method comprising:
(i) applying the undercoat agent according to claim 1 on a substrate and forming an undercoat agent layer;
(ii) forming a layer including a block copolymer on the undercoat agent layer;
(iii) subjecting the layer including the block copolymer to phase separation.

3. The method for producing a structure including a phase-separated structure according to claim 2, wherein in (i), after the undercoat agent is applied on the substrate, a heat treatment is performed at a temperature of 200° C. or lower.
